(19) United States
(12) Patent Application Publication
(10) Pub. No.: US 2026/0095174 A1
(43) Pub. Date: Apr. 2, 2026

(54) SEMICONDUCTOR DEVICE

(71) Applicant: ROHM CO., LTD., Kyoto (JP)

(72) Inventor: Yuji OSUMI, Kyoto (JP)

(73) Assignee: ROHM CO., LTD., Kyoto (JP)

(21) Appl. No.: 19/337,505

(22) Filed: Sep. 23, 2025

(30) Foreign Application Priority Data
Sep. 30, 2024 (JP) 2024-170827

(51) Int. Cl. H03K 17/082; H03K 17/08

(52) U.S. Cl. CPC H03K 17/0822; H03K 2017/0806

(57) ABSTRACT

A semiconductor device includes a chip having a first main surface, a p-type first well region formed in a surface layer of the first main surface, and an active clamp circuit interposed between the drain terminal and the gate control circuit. The active clamp circuit includes a plurality of diode elements that are connected in series and are formed in a surface layer of the first well region in a diode formation region set in the first main surface. The plurality of diode elements include two first diode elements, and second diode elements with a shorter outer peripheral distance in a first element direction than an outer peripheral distance of the first diode elements. Two of the first diode elements are connected to the drain terminal side of the second diode elements.

### CROSS REFERENCE TO RELATED APPLICATION

This application is based upon and claims the benefit of priority of the prior Japanese Patent Application No. 2024-170827, filed on Sep. 30, 2024, the entire contents of which are incorporated herein by reference.

### TECHNICAL FIELD

The present disclosure relates to a semiconductor device.

### BACKGROUND ART

WO/2022/210052 discloses a configuration including a semiconductor chip having a main surface, a main transistor formed on the main surface so as to allow individual control thereof, and an active clamp circuit. If a counter electromotive force is inputted to the main transistor, the active clamp circuit controls the output voltage to protect the main transistor from the counter electromotive force.

### BRIEF DESCRIPTION OF THE DRAWINGS

FIG. 1 is a schematic plan view of a semiconductor device according to an embodiment of the present disclosure.

FIG. 2 is a cross-sectional view along the line II-II in FIG. 1.

FIG. 3 is a schematic circuit diagram showing an electric configuration of the semiconductor device shown in FIG. 1.

FIG. 4 is a schematic circuit diagram showing a configuration of an output transistor.

FIG. 5A is a schematic circuit diagram showing a configuration of an active clamp circuit shown in FIG. 1.

FIG. 5B is a schematic circuit diagram showing a configuration of a main portion of a voltage clamp circuit shown in FIG. 1.

FIG. 6 is a layout view of a first main surface in a diode formation region shown in FIG. 1.

FIG. 7 is a plan view of the diode formation region.

FIG. 8 is an expanded view of a region of FIG. 6 encircled by a dash-dotted line VIII.

FIG. 9 is an enlarged view of a region of FIG. 7 surrounded by a dash-dotted line IX.

FIG. 10 is a layout view of a first main surface in a first diode element shown in FIG. 6.

FIG. 11 is a cross-sectional view along the line XI-XI in FIG. 9.

FIG. 12 is a cross-sectional view along the line XII-XII in FIG. 9.

FIG. 13 is a layout view of a first main surface in a second diode element shown in FIG. 6.

FIG. 14 is a cross-sectional view along the line XIV-XIV in FIG. 9.

FIG. 15 is a cross-sectional view along the line XV-XV in FIG. 13.

FIG. 16A is a cross-sectional view along the line XVIA-XVIA in FIG. 8.

FIG. 16B is a schematic diagram showing an electric configuration of the semiconductor device.

FIG. 16C shows Modification Example 1 in which the layout of the second diode element has been modified, and corresponds to FIG. 13.

FIG. 16D shows Modification Example 2 in which a third diode element is additionally formed in the diode formation region, and corresponds to FIG. 7.

FIG. 16E is a layout view of a first main surface in the third diode element shown in FIG. 16D.

FIG. 17 is a plan view showing Embodiment 2 of an arrangement of the first diode element and the second diode element.

FIG. 18 is a plan view showing Embodiment 3 of an arrangement of the first diode element and the second diode element.

FIG. 19 is an enlarged cross-sectional view along the line XIX-XIX in FIG. 18.

FIG. 20 is a plan view showing Embodiment 4 of an arrangement of the first diode element and the second diode element.

FIG. 21 is a plan view showing Embodiment 5 of an arrangement of the first diode element and the second diode element.

FIG. 22 is a plan view showing Embodiment 6 of an arrangement of the first diode element and the second diode element.

FIG. 23 is an enlarged cross-sectional view along the line XXIII-XXIII in FIG. 22.

### DETAILED DESCRIPTION OF EMBODIMENTS

Embodiments will be explained in detail below with reference to the attached drawings. The attached drawings are schematic views that do not depict reality precisely, and are not necessarily to scale. Among the attached drawings, corresponding structures are assigned the same reference characters, and redundant explanations thereof are either omitted or simplified. For structures with omitted or simplified explanations, the explanations made prior to such omission or simplification apply.

If language such as “substantially equivalent” is used in a description with an object for comparison, this language includes cases in which the numerical values (embodiments) are equivalent to the numerical values (embodiments) of the object for comparison, and also include a numerical error (embodiment error) of ±10% of the numerical value (embodiment) of the object for comparison. The embodiments are labeled “1,” “2,” “3,” or the like, but these are symbols affixed to the names of the respective structures in order to clarify the order of explanation, and are not meant to limit the name of each structure.

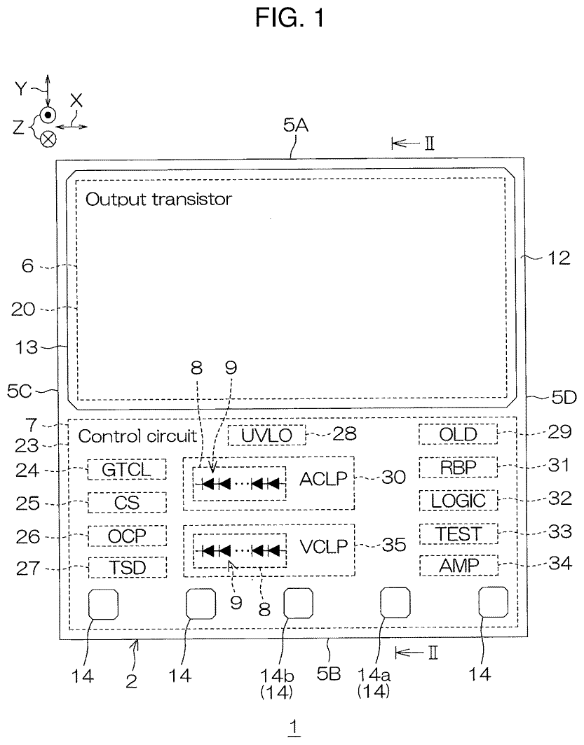

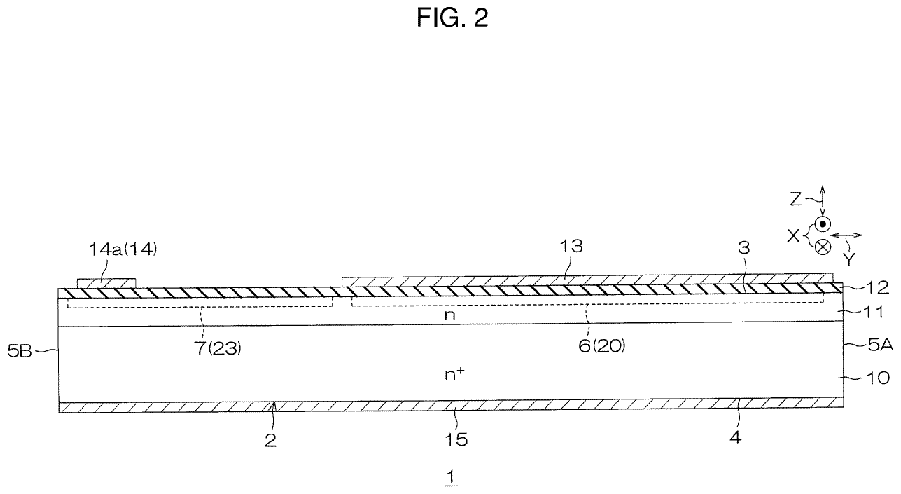

FIG. 1 is a plan view of a semiconductor device 1 according to an embodiment of the present disclosure. FIG. 2 is a cross-sectional view along the line II-II in FIG. 1. With reference to FIGS. 1 and 2, the semiconductor device 1 includes a chip 2 formed in a rectangular cuboid shape. The chip 2 is a Si chip including a Si single crystal in this embodiment.

The chip 2 may be made of a wide-bandgap semiconductor chip including a wide-bandgap semiconductor single crystal. The wide-bandgap semiconductor is a semiconductor having a bandgap greater than the bandgap of Si. GaN (gallium nitride), SiC (silicon carbide), C (diamond), and the like are examples of a wide-bandgap semiconductor. The chip 2 may be an SiC chip including an SiC single crystal, for example.

With reference to FIG. 2, the chip 2 has a first main surface 3 on one side, a second main surface 4 on the other side, and first to fourth side faces 5A to 5D that connect the first main surface 3 to the second main surface 4. The first main surface 3 and the second main surface 4 are formed into a quadrilateral shape from a plan view seen from a normal line direction Z thereof (hereinafter simply referred to as a “plan view”). The normal line direction Z is also the thickness direction of the chip 2.

The first main surface 3 is a circuit surface on which various circuit structures constituting the electronic circuit are formed. The second main surface 4 is a non-circuit surface that does not have circuit structures.

With reference to FIG. 1, the first side face 5A and the second side face 5B extend in a first direction X along the first main surface 3, and oppose each other in a second direction Y that intersects (specifically perpendicularly) with the first direction X. The third side face 5C and the fourth side face 5D extend in the second direction Y, and oppose each other in the first direction X.

The semiconductor device 1 includes an output region 6 provided on the first main surface 3. The output region 6 is a region having an electronic circuit (circuit device) configured so as to generate an output signal to be outputted to an external unit. In this embodiment, the output region 6 is delineated on a region towards the first side face 5A of the first main surface 3. The output region 6 is delineated as a polygon having four sides (in this embodiment, a quadrilateral shape) that are parallel to the peripheral edges of the first main surface 3 in a plan view.

The semiconductor device 1 includes a control region 7 provided in a region of the first main surface 3 differing from the output region 6. The control region 7 is a region having a plurality of types of electronic circuits (circuit devices) configured so as to generate a control signal for controlling the output region 6. In this embodiment, the control region 7 is delineated on a region towards the second side face 5B of the first output region 6, and opposes the output region 6 in the second direction Y. In this embodiment, the control region 7 is delineated as a polygon having four sides (in this embodiment, a quadrilateral shape) that are parallel to the peripheral edges of the first main surface 3 in a plan view.

The semiconductor device 1 includes at least one diode formation region 8 in the first main surface 3. The semiconductor device 1 may include a plurality of diode formation regions 8. In this embodiment, the semiconductor device 1 includes a diode formation region 8 corresponding to an active clamp circuit 30 (clamp circuit). The semiconductor device 1 further includes a diode formation region 8 corresponding to a voltage clamp circuit 35 (clamp circuit). The diode formation region 8 corresponding to the active clamp circuit 30 and the diode formation region 8 corresponding to the voltage clamp circuit 35 are formed with a gap therebetween. A configuration may be adopted in which only one of the diode formation regions 8 is provided, and the other is omitted.

The individual diode formation regions 8 have a planar area less than that of the control region 7, and are delineated towards the inside of the control region 7. The individual diode formation regions 8 have formed therein a diode group 9 constituted of a plurality of diode elements connected in series in the reverse direction.

With reference to FIG. 2, the semiconductor device 1 includes an n-type (first conductivity type) drain region 10 formed on the surface layer of the second main surface 4. The n-type impurity concentration of the drain region 10 may be 1×10¹⁸ cm⁻³ to 1×10²¹cm⁻³, inclusive. The drain region 10 is formed as a layer extending along the second main surface 4 on the entire surface layer of the second main surface 4, and is exposed through the second main surface 4 and the first to fourth side faces 5A to 5D. The drain region 10 may have a thickness of 50 μm to 400 μm, inclusive. It is preferable that the drain region 10 have a thickness of 50 μm to 200 μm, inclusive. It is more preferable that the drain region 10 have a thickness of 150 μm or less. In this embodiment, the drain region 10 is made of an n-type semiconductor substrate (Si substrate).

The semiconductor device 1 includes an n-type drift region 11 formed in the surface layer of the first main surface 3. The drift region 11 has an n-type impurity concentration lower than that of the drain region 10. The n-type impurity concentration of the drift region 11 may be 1×10¹⁵ cm⁻³ to 1×10¹⁸ cm⁻³, inclusive. The drift region 11 is formed as a layer that extends along the first main surface 3 in the output region 6 and the control region 7. Specifically, the drift region 11 is formed as a layer extending along the first main surface 3 on the entire surface layer of the first main surface 3, and is exposed through the first main surface 3 and the first to fourth side faces 5A to 5D.

The drift region 11 is electrically connected to the drain region 10 in the chip 2. The drift region 11 has a thickness less than that of the drain region 10. The thickness of the drift region 11 may be 1 μm to 20 μm, inclusive. It is preferable that the drift region 11 have a thickness of 5 μm to 15 μm, inclusive. It is particularly preferable that the drift region 11 have a thickness of 10 μm or less. In this embodiment, the drift region 11 is made of an n-type epitaxial layer (Si epitaxial layer).

The semiconductor device 1 includes an interlayer insulating layer 12 that covers the first main surface 3. The interlayer insulating layer 12 covers both the output region 6 and the control region 7. The interlayer insulating layer 12 may cover the entire first main surface 3 so as to be continuous with the peripheral edges (first to fourth side faces 5A to 5D) of the first main surface 3. Of course, the interlayer insulating layer 12 may be formed at a gap inward from the peripheral edges of the first main surface 3 so as to expose the peripheral edges of the first main surface 3. The interlayer insulating layer 12 may include a silicon oxide film and/or a silicon nitride film.

The semiconductor device 1 includes a plurality of terminals 13 to 15 that are disposed on one or both (in this embodiment, both) of the first main surface 3 and the second main surface 4. The plurality of terminals 13 to 15 include a source terminal 13, a plurality of control terminals 14, and a drain terminal 15.

In this embodiment, the source terminal 13 is provided as an output terminal electrically connected to a load, and is disposed on a portion of the interlayer insulating layer 12 covering the output region 6. The source terminal 13 may cover the entire output region 6 in a plan view. The source terminal 13 may include at least one of a pure Al layer, a Cu layer, an AlCu alloy layer, an AlSiCu alloy layer, and an AlSi alloy layer.

With reference to FIGS. 1 and 2, the plurality of control terminals 14 are terminals electrically connected to various electronic circuits in the control region 7, and are disposed on a portion of the interlayer insulating layer 12 covering the output region 7. The plurality of control terminals 14 are disposed at a gap from each other along the peripheral edges of the control region 7 (peripheral edges of the first main surface 3).

The planar area of each control terminal 14 is set to within a range allowing for connection thereto of bonding wires. The planar area of each control terminal 14 may be 1/10 or less the planar area of the source terminal 13. The plurality of control terminals 14 may include at least one of a pure Al layer, a Cu layer, an AlCu alloy layer, an AlSiCu alloy layer, and an AlSi alloy layer.

The plurality of control terminals 14 include at least one ground terminal 14a fixed at ground potential, and at least one input terminal 14b that applies an electrical signal to the control region 7. The location at which the ground terminal 14a is disposed is arbitrary. The ground terminal 14a may be disposed towards the inside of the control region 7 in a plan view, may be disposed at a portion along one side of the first main surface 3, or may be disposed at a corner of the first main surface 3. The ground terminal 14a is connected to a bonding wire, and has applied thereto a ground potential from an external source via the bonding wire.

The location at which the input terminal 14b is disposed is arbitrary. The input terminal 14b may be disposed towards the inside of the control region 7 in a plan view, may be disposed at a portion along one side of the first main surface 3, or may be disposed at a corner of the first main surface 3.

In this embodiment, an example is described in which the input terminal 14b is constituted of a test terminal to which a test signal for testing the electrical characteristics of a control circuit 23 during the manufacturing process is inputted. The test terminal is provided to be abutted by a probe of an electrical characteristic test device, and is configured to allow input thereto of a test signal from the probe.

The input terminal 14b is a structure to which a bonding wire is not connected in the semiconductor device 1 once manufacturing thereof is complete. In other words, the input terminal 14b is formed as an open terminal (dummy terminal). The open terminal does not receive a signal (potential) from an external source, and is formed so as to be electrically floating.

If the semiconductor device 1 is installed in a semiconductor package, for example, the entirety of the input terminal 14b is covered by an insulator (sealing resin including a plurality of fillers and a matrix resin, for example), and is electrically insulated from other structures. Of course, a configuration may be adopted in which the input terminal 14b is electrically connected to a lead terminal of the semiconductor package via the bonding wire, and a test signal is inputted thereto even after the semiconductor device 1 is installed in the semiconductor package.

With reference to FIG. 2, in this embodiment, the drain terminal 15 as an example of the power source terminal directly covers the second main surface 4 of the chip 2. In other words, in this embodiment, the semiconductor device 1 is a high-side switching device that is electrically interposed between the power source and the load. The drain terminal 15 is electrically connected to the drain region 10 in the second main surface 4 The drain terminal 15 may cover the entire second main surface 4 so as to be continuous with the peripheral edges (first to fourth side faces 5A to 5D) of the second main surface 4.

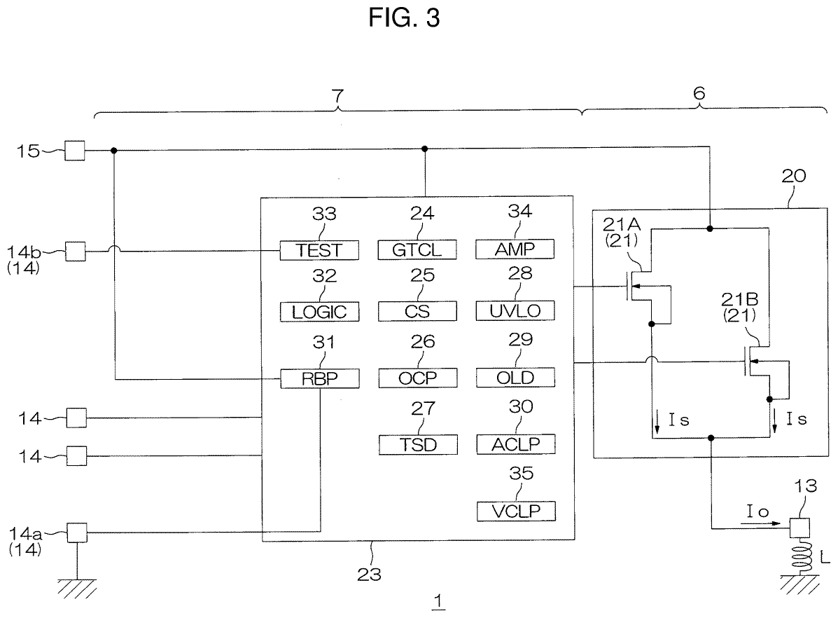

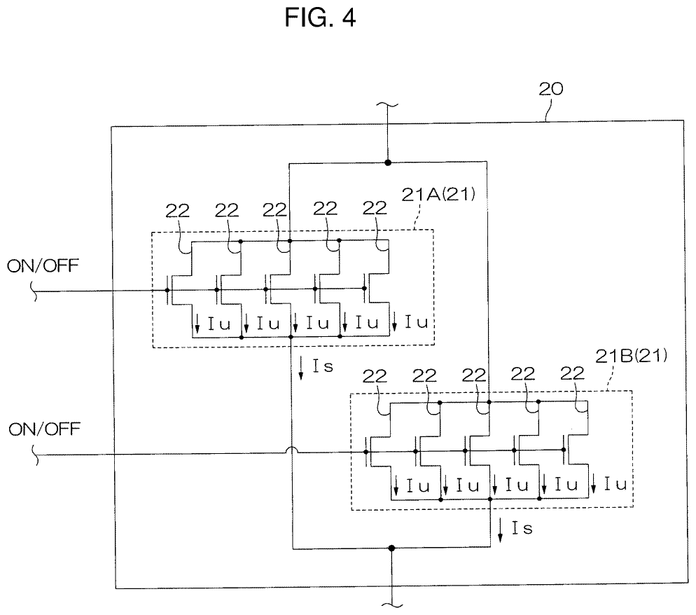

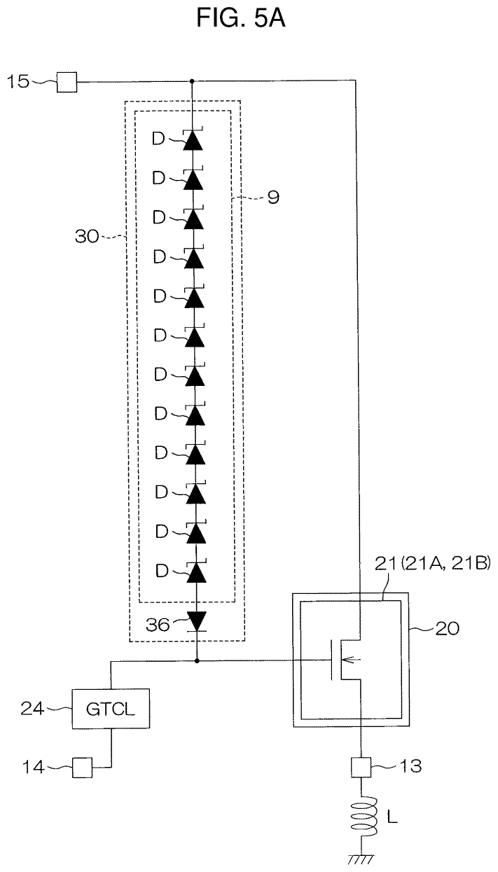

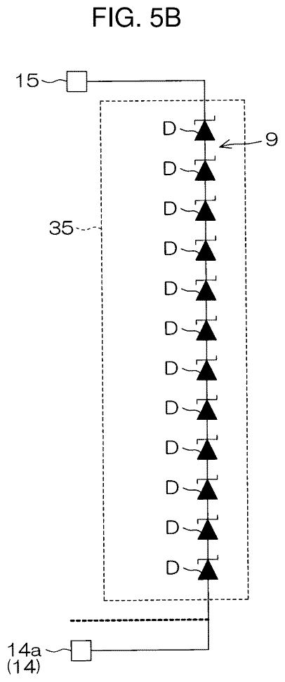

FIG. 3 is a schematic circuit diagram showing an electric configuration of the semiconductor device 1 shown in FIG. 1. FIG. 4 is a schematic circuit diagram showing a configuration of an output transistor 20. FIG. 5A is a schematic circuit diagram that schematically shows a configuration of the active clamp circuit 30 shown in FIG. 3. FIG. 5B is a schematic circuit diagram showing a configuration of a main portion of the voltage clamp circuit 35 shown in FIG. 3.

FIG. 3 shows an example in which an inductive load L, which is an example of the load, is electrically connected to the source terminal 13, in order to show an operation example of the semiconductor device 1. The inductive load L is not a constituent element of the semiconductor device 1. Thus, a configuration including the semiconductor device 1 and the inductive load L may be referred to as an “inductive load driving device” or an “inductive load control device.” Relays, solenoids, lamps, motors, and the like are examples of the inductive load L. The inductive load L may be designed to be installed in a vehicle. In other words, the semiconductor device 1 may be a vehicle-installed semiconductor device.

With reference to FIGS. 3 and 4, the semiconductor device 1 includes the output transistor 20 formed in the output region 6. In this embodiment, the output transistor 20 is constituted of a split-gate transistor including one main drain, one main source, and a plurality of main gates. The main drain is electrically connected to the drain terminal 15. The main source is electrically connected to the source terminal 13.

The plurality of main gates are configured such that a plurality of electrically independent gate signals (gate potentials) are individually inputted thereto. The output transistor 20 generates a single output current Io (output signal) in response to the plurality of gate signals. In other words, the output transistor 20 is constituted of a multi-input/single-output-type switching device. The output current Io is a drain/source current that flows between the main drain and the main source. The output current Io is outputted to outside of the chip 2 (inductive load L) via the source terminal 13.

The output transistor 20 includes a plurality (two or more) of system transistors 21 controlled in an electrically independent manner from each other. In this embodiment, the plurality of system transistors 21 include a first system transistor 21A and a second system transistor 21B. The plurality of system transistors 21 are collectively formed in the output region 6. The plurality of system transistors 21 are connected in parallel such that the plurality of gate signals are individually inputted thereto, and are configured such that an ON-state system transistor 21 and an OFF-state system transistor 21 are both present.

The plurality of system transistors 21 each include a system drain, a system source, and a system gate. The plurality of system drains are electrically connected to the main drain (drain terminal 15). The plurality of system sources are electrically connected to the main source (source terminal 13). Each system gate is electrically connected to each main gate. In other words, each system gate constitutes each main gate.

The plurality of system transistors 21 each generate a system current Is in response to the corresponding gate signal. Each system current Is is a drain/source current that flows between the system drain and the system source of each system transistor 21. The plurality of system currents Is may have different values, or may have substantially the same value. The plurality of system currents Is are added between the main drain and the main source. As a result, a single output current Io constituted of the sum of the plurality of system currents Is is generated.

With reference to FIG. 4, the plurality of system transistors 21 include one or more unit transistors 22 that are systematized (grouped) as individual units to be controlled. Specifically, the plurality of system transistors 21 are constituted of a parallel circuit including one or more unit transistors 22. In this embodiment, the plurality of unit transistors 22 are each constituted of a trench gate vertical transistor. The plurality of system transistors 21 may be constituted of the same number of unit transistors 22 or of a different number of unit transistors 22.

Each unit transistor 22 includes a unit drain, a unit source, and a unit gate. The unit drain of each unit transistor 22 is electrically connected to the system drain of the corresponding system transistor 21. The unit source of each unit transistor 22 is electrically connected to the system source of the corresponding system transistor 21. The unit gate of each unit transistor 22 is electrically connected to the system gate of the corresponding system transistor 21.

The plurality of system transistors 22 each generate a unit current Iu in response to the corresponding gate signal. Each unit current Iu is a drain/source current that flows between the unit drain and the unit source of each unit transistor 22. The plurality of unit currents Iu may have different values, or may have substantially the same value. The plurality of unit currents Iu are added between the corresponding system drain and system source. As a result, the system current Is constituted of the sum of the plurality of unit currents Iu is generated.

In this manner, the output transistor 20 is configured such that the first system transistor 21A and the second system transistor 21B can be controlled to be ON/OFF while being electrically independent from each other. In other words, the output transistor 20 is configured to allow both the first system transistor 21A and the second system transistor 21B to be simultaneously set to the ON state. Also, the output transistor 20 is configured to allow either one of the first system transistor 21A and the second system transistor 21B to be set to ON while the other is set to be OFF.

When both the first system transistor 21A and the second system transistor 21B are simultaneously set to be ON, the channel utilization rate of the output transistor 20 increases, which decreases the ON resistance. When either one of the first system transistor 21A and the second system transistor 21B is set to be ON while the other is set to be OFF, the channel utilization rate of the output transistor 20 decreases, which increases the ON resistance. In other words, the output transistor 20 is constituted of a variable ON resistance switching device.

With reference to FIGS. 1 and 3, the semiconductor device 1 includes the control circuit 23 formed in the output region 7 so as to be electrically connected to the output transistor 20. The control circuit 23 may be referred to as a “control IC.” The control circuit 23 includes various function circuits and, together with the output transistor 20, constitutes an intelligent power device (IPD). The IPD may be referred to as an “intelligent power module (IPM),” an “intelligent power switch (IPS),” a “smart power driver,” a “smart MISFET (smart MOSFET),” or a “protected MISFET (protected MOSFET).”

In this embodiment, the control circuit 23 includes a gate control circuit 24, a current monitor circuit 25, an overcurrent protection circuit 26, an overheating protection circuit 27, a low voltage error operation avoidance circuit 28, an open load detection circuit 29, the active clamp circuit 30, a power source reverse connection protection circuit 31, a logic circuit 32, a test circuit 33, an amplifier circuit 34, and the voltage clamp circuit 35. The control circuit 23 need not necessarily include all of the aforementioned function circuits as long as at least one of the function circuits is included.

The current monitor circuit 25 may be referred to as a current sense circuit (CS circuit). The overcurrent protection circuit 26 may be referred to as an OCP circuit. The overheating protection circuit 27 may be referred to as a thermal shutdown circuit (TSD circuit). The low voltage error operation avoidance circuit 28 may be referred to as an undervoltage lockout circuit (UVLO circuit). The open load detection circuit 29 may be referred to as an OLD circuit. The power source reverse connection protection circuit 31 may be referred to as a reverse battery protection circuit (RBP circuit). The amplification circuit 34 may be referred to as an AMP circuit.

The gate control circuit 24 is configured to generate a gate signal that controls the output transistor 20 so as to be ON or OFF. Specifically, the gate control circuit 24 generates a plurality of gate signals that individually control the plurality of system transistors 21 so as to be ON or OFF. In other words, in this embodiment, the gate control circuit 24 generates a first gate signal that individually controls the first system transistor 21A to be ON or OFF and generates a second gate signal that individually controls the second system transistor 21B to be ON or OFF, electrically independent of the first system transistor 21A.

The current monitor circuit 25 generates a monitor current that monitors the output current Io of the output transistor 20, and outputs the monitor current to other circuits. For example, the monitor circuit may be configured so as to include a transistor having a similar configuration to the output transistor 20, and so as to generate a monitor current coordinated with the output current Io as a result of the transistor being controlled to be ON or OFF simultaneously to the output transistor 20. Of course, the current monitor circuit 25 may be configured to generate the monitor current in coordination with one or more system currents Is.

The overcurrent protection circuit 26 generates an electrical signal that controls the gate control circuit 24 on the basis of the monitor current from the current monitor circuit 25, and controls the output transistor 20 so as to be ON or OFF in coordination with the gate control circuit 24. The overcurrent protection circuit 26 may, for example, be configured so as to make a determination that the output transistor 20 is in an overcurrent state if the monitor current is greater than or equal to a prescribed threshold, and control some or all of the output transistors 20 (plurality of system transistors 21) to be in the OFF state in coordination with the gate control circuit 24. Also, the overcurrent protection circuit 26 may be configured so as to transition the output transistor 20 to normal operation in coordination with the gate control circuit 24 if the monitor current falls below the prescribed threshold.

The overheating protection circuit 27 includes a first temperature sensing device (e.g., temperature sensing diode) that detects the temperature of the output region 6, and a second temperature sensing device (e.g., temperature sensing diode) that detects the temperature of the control region 7. The overheating protection circuit 27 generates an electrical signal that controls the gate control circuit 24 on the basis of a first temperature detection signal from the first temperature sensing device and a second temperature detection signal from the second temperature sensing device, and controls the output transistor 20 so as to be ON or OFF in coordination with the gate control circuit 24.

The overheating protection circuit 27 may, for example, be configured so as to make a determination that the output region 6 is in an overheated state if the difference between the first temperature detection signal and the second temperature detection signal is greater than or equal to a prescribed threshold, and control some or all of the output transistors 20 (plurality of system transistors 21) to be in the OFF state in coordination with the gate control circuit 24. Also, the overheating protection circuit 27 may be configured so as to transition the output transistor 20 to normal operation in coordination with the gate control circuit 24 if the difference falls below the prescribed threshold.

The low voltage error operation avoidance circuit 28 is configured to avoid erroneous operation of various function circuits in the control circuit 23 if a startup voltage for starting up the control circuit 23 is less than a prescribed value. For example, the low voltage error operation avoidance circuit 28 may be configured to start up the control circuit 23 if the startup voltage reaches a value greater than or equal to a prescribed threshold voltage, and to stop the control circuit 23 if the startup voltage falls below the threshold voltage. The threshold voltage may have hysteresis characteristics.

The open load detection circuit 29 determines the electrical connection state to the inductive load L. For example, the open load detection circuit 29 may be configured to monitor the inter-terminal voltage of the output transistor 20, and determine that the inductive load L is in an open state when the inter-terminal voltage is at or above a prescribed threshold. The open load detection circuit 29 may alternatively be configured to determine that the inductive load L is in an open state when the monitor current is at or below a prescribed threshold, for example.

With reference to FIG. 5A, the active clamp circuit 30 is electrically connected to the main drain terminal and at least one main gate (e.g., the system gate of the first system transistor 21A) of the output transistor 20. In the example shown in FIG. 5A, the active clamp circuit 30 is electrically connected to the drain terminal 15 and the gate control circuit 24. The gate control circuit 24 is electrically connected to the control terminal 14.

The active clamp circuit 30 includes the diode group 9 configured by connecting a plurality of diodes D, which are Zener diodes, in series. The active clamp circuit 30 includes a pn junction diode 36 that is connected in series so as to be reverse biased to the diode group 9. The pn junction diode is a reverse current prevention diode that prevents a reverse current from the output transistor 20.

The cathode of the diode group 9 may be electrically connected to the drain terminal 15. In other words, the cathode of the diode group 9 is connected to the drain terminal 15. The anode of the diode group 9 may be connected to gate control circuit 24 (control terminal 14). In other words, the anode of the diode group 9 is connected to the gate control circuit 24 (towards the control terminal 14).

With reference to FIGS. 1 and 3, the active clamp circuit 30 controls some or all of the output transistors 20 to be ON in coordination with the gate control circuit 24 when a counter-electromotive force resulting from the inductive load L is applied to the output transistor 20.

Specifically, the output transistor 20 is controlled according to a plurality of types of operation modes including normal operation, first OFF operation, active clamp operation, and second OFF operation.

In normal operation, both the first system transistor 21A and the second system transistor 21B are controlled so as to be simultaneously set to the ON state. As a result, the channel utilization rate of the output transistor 20 increases, which decreases the ON resistance. In the first OFF operation, both the first system transistor 21A and the second system transistor 21B are controlled so as to be simultaneously switched from the ON state to the OFF state. The counter-electromotive force resulting from the inductive load L is applied to both the first system transistor 21A and the second system transistor 21B.

The active clamp operation is an operation to absorb (consume) the energy accumulated in the inductive load L using the output transistor 20, and is executed when the counter-electromotive force resulting from the inductive load L is at or above a prescribed threshold voltage. In the active operation, the first system transistor 21A is controlled to be switched from the OFF state to the ON state while the second system transistor 21B is controlled to be (remain) in the OFF state.

The channel utilization rate of the output transistor 20 during the active operation is less than the channel utilization rate of the output transistor 20 during normal operation. The ON resistance of the output transistor 20 during the active operation is greater than the ON resistance of the output transistor 20 during normal operation. As a result, a rapid increase in temperature is mitigated in the output transistor 20 during the active operation, and the active clamp durability is increased.

The second OFF operation is executed when the counter-electromotive force is less than a prescribed threshold voltage. In the second OFF operation, the first system transistor 21A is controlled to be switched from the ON state to the OFF state while the second system transistor 21B is controlled to be (remain) in the OFF state. In this manner, the counter-electromotive force (energy) of the inductive load L is absorbed by a portion of the output transistor 20 (in this case, the first system transistor 21A). Of course, during the active operation, the first system transistor 21A may be controlled to be (remain) in the OFF state while the second system transistor 21B is controlled to be in the ON state.

The power source reverse connection protection circuit 31 is configured to detect a reverse voltage when the power source is connected in reverse, and to protect the control circuit 23 and the output transistor 20 from the reverse voltage (reverse current). The logic circuit 32 is configured to generate an electrical signal supplied to the various circuits inside the control circuit 23.

The test circuit 33 is formed on the first main surface 3 so as to be electrically interposed between the input terminal 14b and the drain terminal 15, and is electrically connected to the input terminal 14b and the drain terminal 15. The test circuit 33 is formed in order to indirectly evaluate the electrical characteristics of the control circuit 23 during the manufacturing process. It is preferable that the test circuit 33 be disposed in a region adjacent to the input terminal 14b in a plan view.

If the semiconductor device 1 is installed in a vehicle, for example, the amplifier circuit 34 is configured to perform amplification processing on detection signals inputted from various sensors installed in the vehicle (e.g., pressure sensor, inertia sensor, MR sensor, etc.) to the semiconductor device 1.

With reference to FIG. 5B, the voltage clamp circuit 35 may be referred to as an overvoltage protection circuit. The voltage clamp circuit 35 includes the diode group 9 including the plurality of diodes D, which are Zener diodes. In FIG. 5B, only a portion of the voltage clamp circuit 35 relevant to the diode group 9 is shown.

The cathode of the diode group 9 is connected to the drain terminal 15. The anode of the diode group 9 may be connected to ground line (ground terminal 14a (control terminal 14)).

Even when an overvoltage is applied to the drain terminal 15, the voltage clamp circuit 35 limits the voltage inputted to the control circuit 23 to within a prescribed clamp voltage range of ground (0V). As a result, the input of an overvoltage to the control circuit 23 can be prevented.

With reference to FIG. 1, as previously described, the semiconductor device 1 includes the diode formation region 8 delineated on the inner portion of the control region 7. The diode formation region 8 is disposed in the first main surface 3 at a gap from the peripheral edge of the control region 7. In the diode formation region 8, the diode group 9 included in the voltage clamp circuit 35 and the diode group 9 included in the active clamp circuit 30 are formed.

The diode group 9 will be explained below. The diode group 9 may be the diode group 9 included in the voltage clamp circuit 35 and/or the diode group 9 included in the active clamp circuit 30. The diode group 9 is formed in the diode formation region 8 (FIG. 1) set in the first main surface 3 of the control region 7 (FIG. 1).

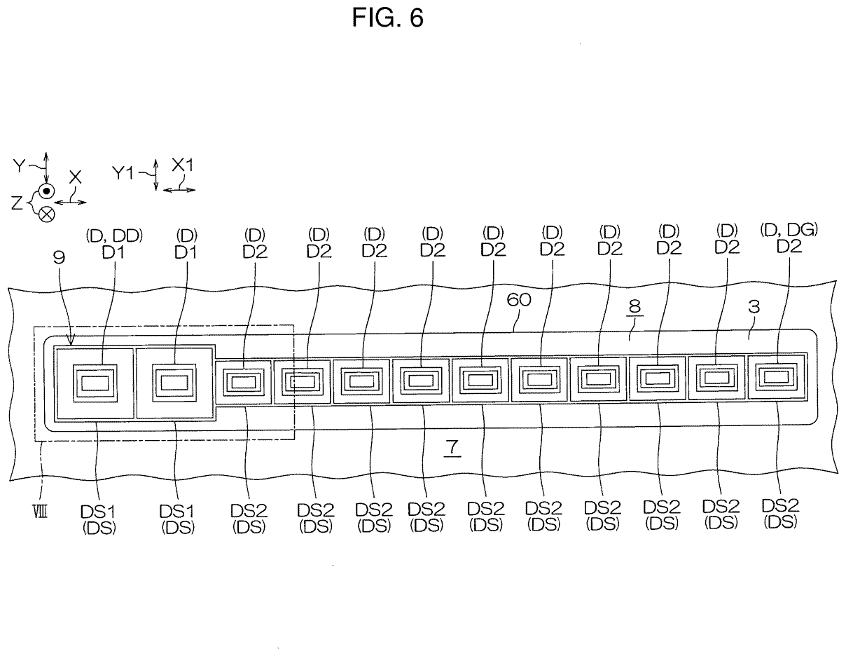

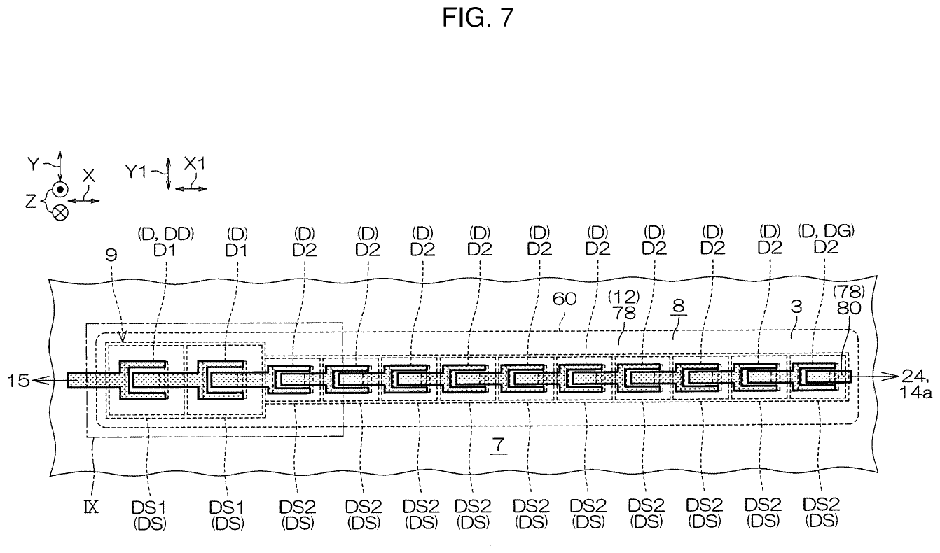

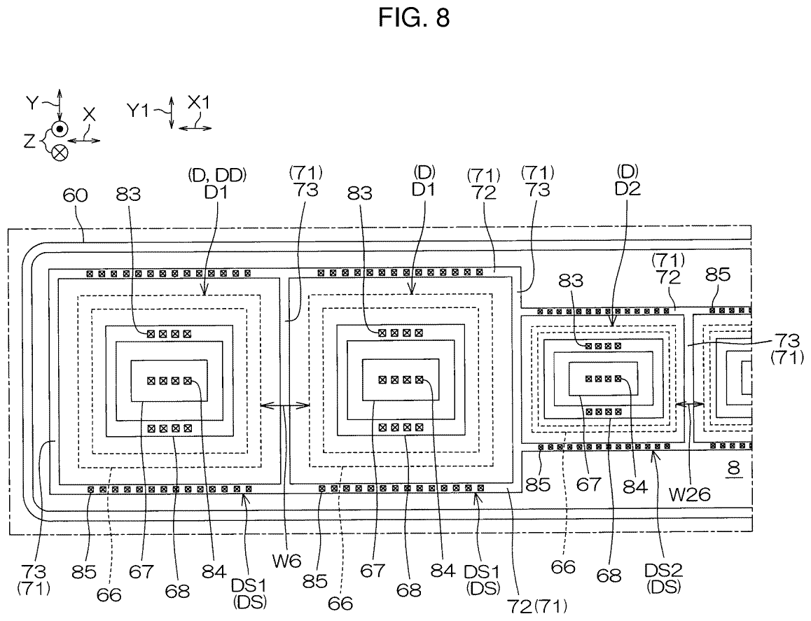

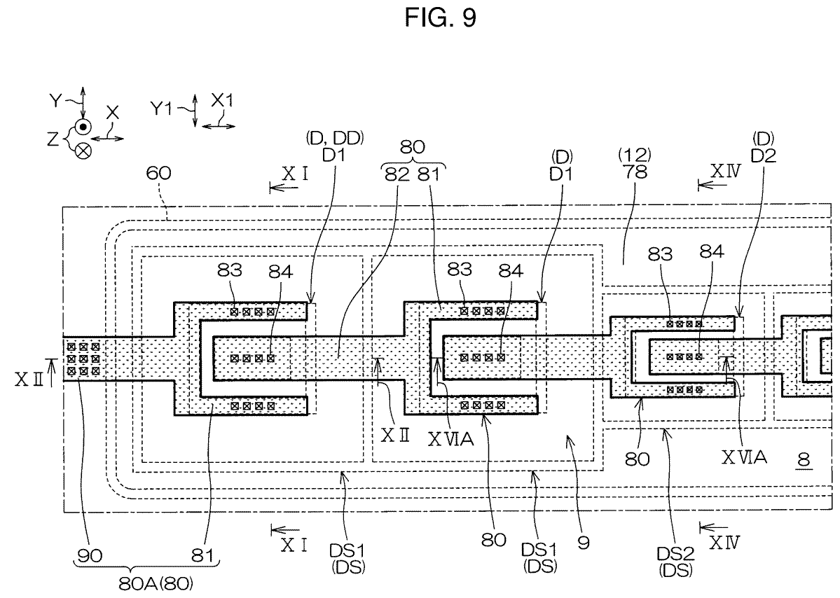

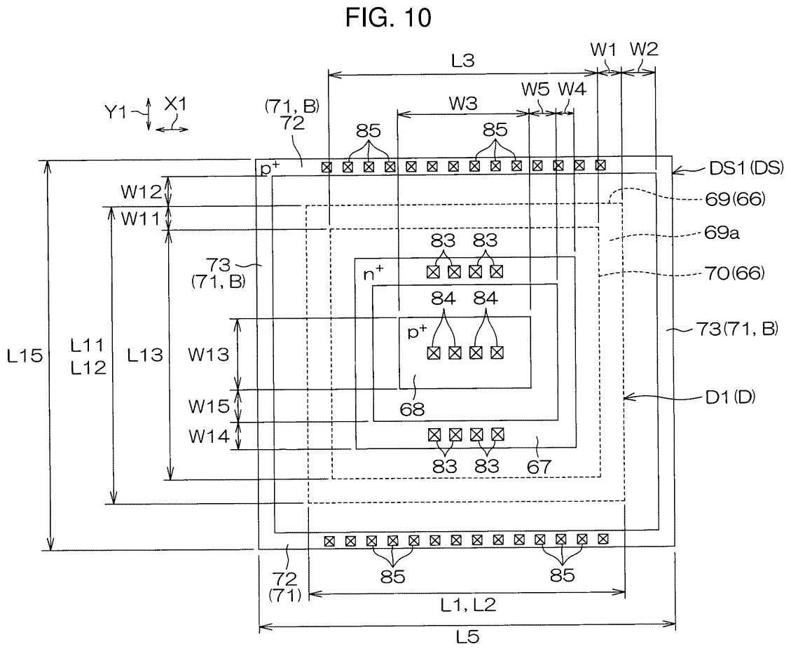

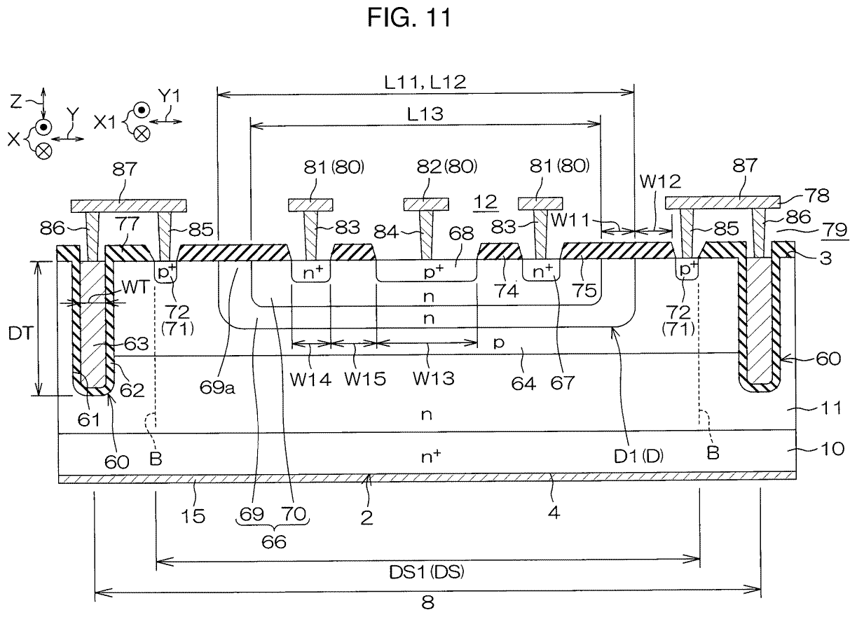

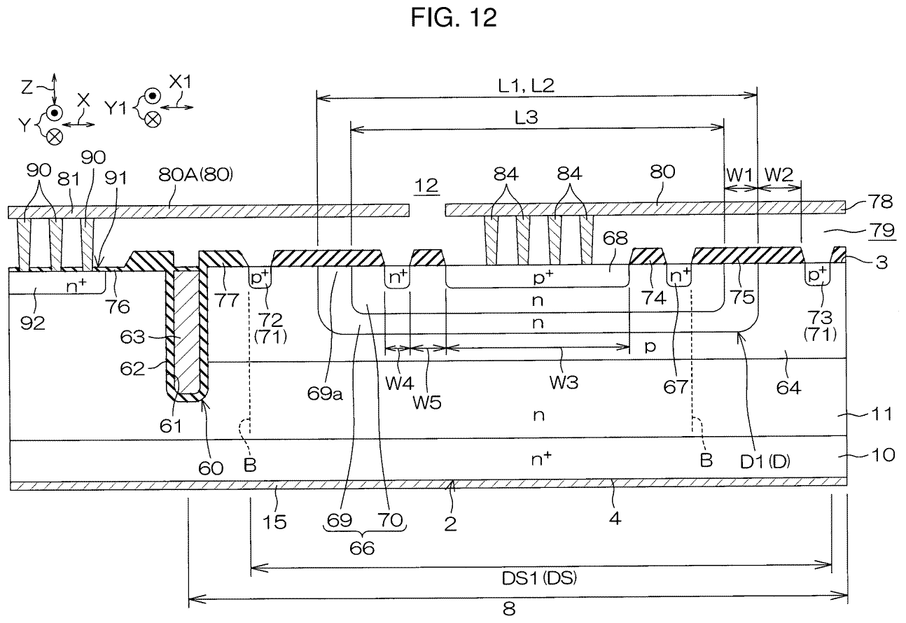

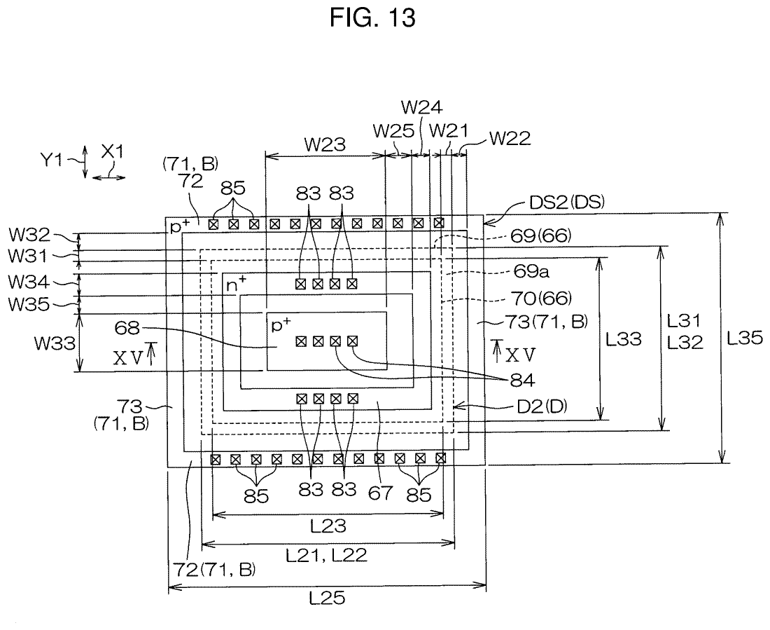

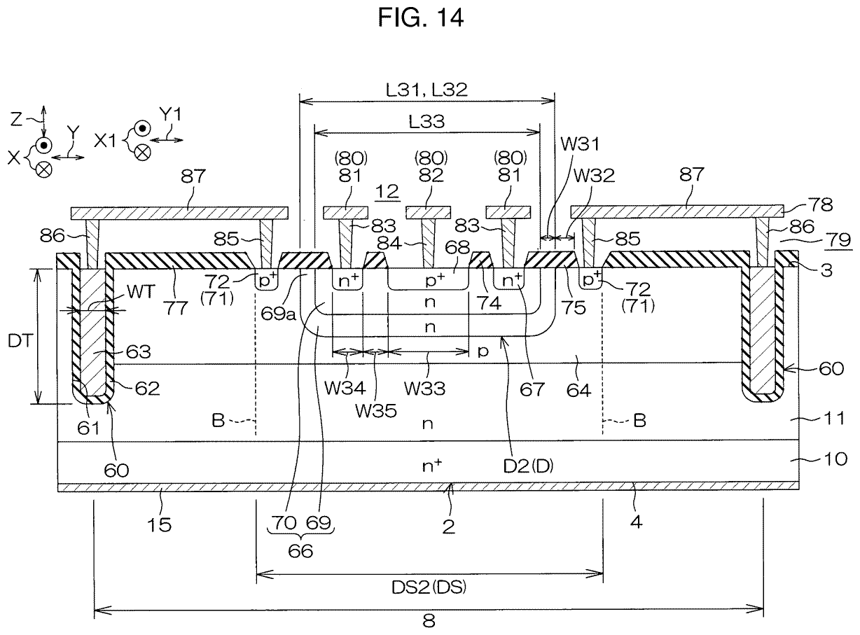

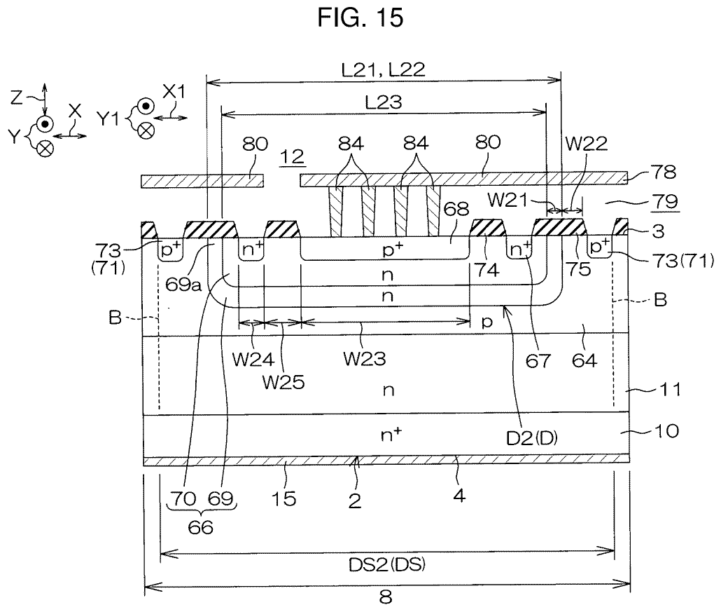

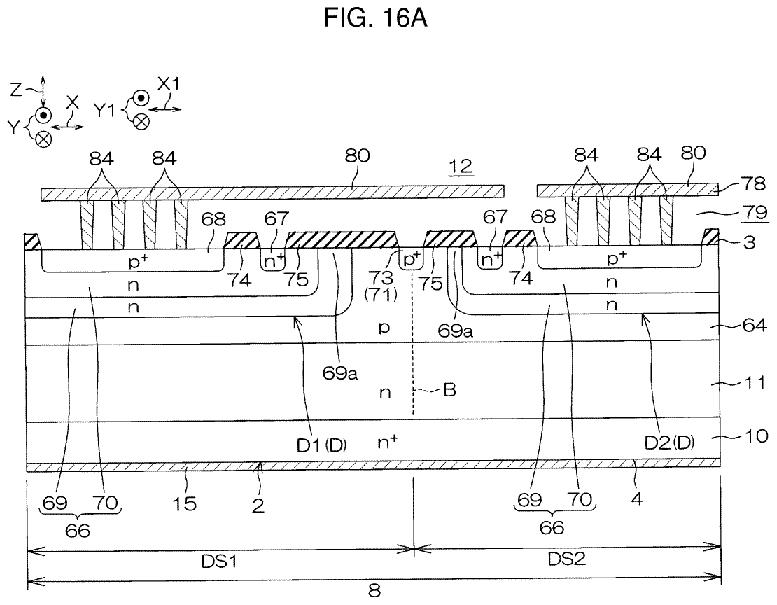

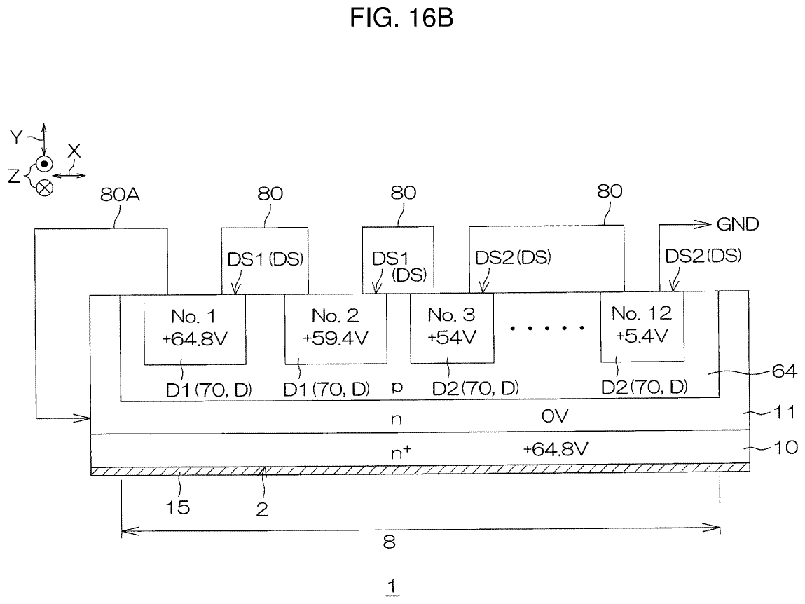

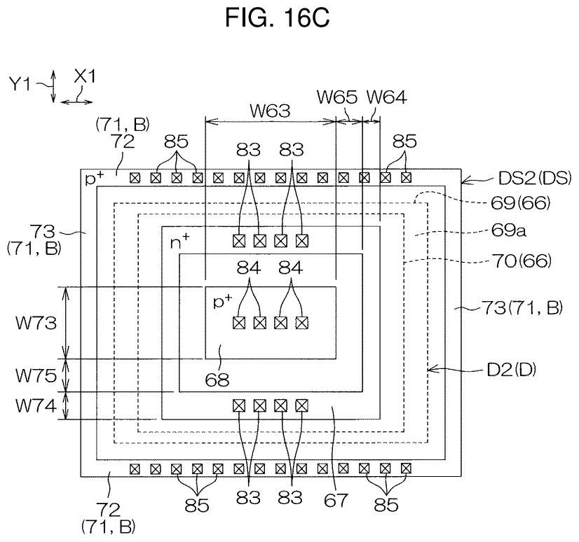

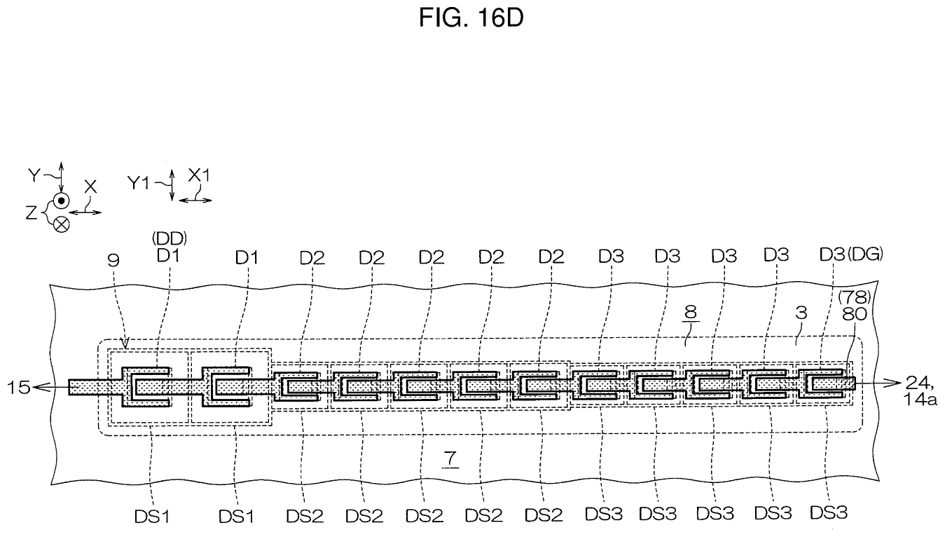

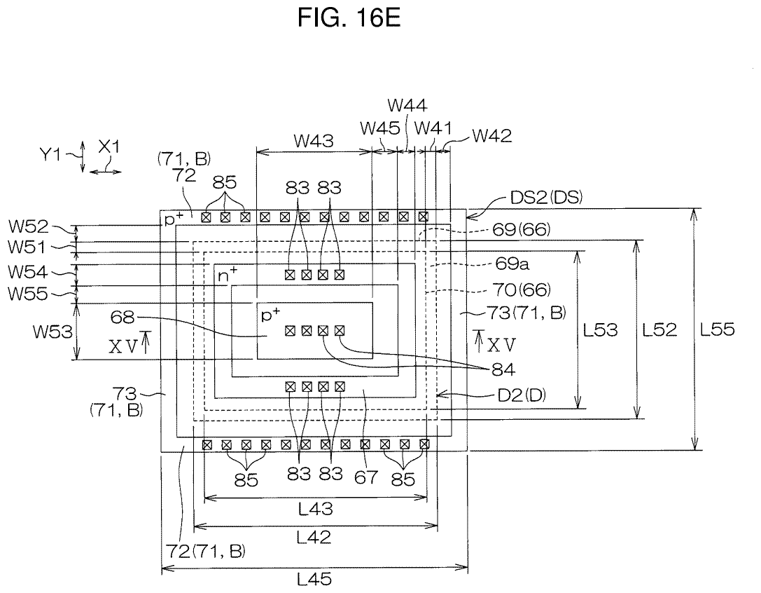

FIG. 6 is a layout view of the first main surface 3 in the diode formation region 8. FIG. 7 is a plan view of the diode formation region 8. FIG. 8 is an expanded view of the region of FIG. 6 encircled by the dash-dotted line VIII. FIG. 9 is an expanded view of the region of FIG. 7 encircled by the dash-dotted line IX. FIG. 10 is a layout view of the first main surface 3 in a first diode element DS1 shown in FIG. 6. FIG. 11 is a cross-sectional view along the line XI-XI in FIG. 9. FIG. 12 is a cross-sectional view along the line XII-XII in FIG. 9. FIG. 13 is a layout view of the first main surface 3 in a second diode element DS2 shown in FIG. 6. FIG. 14 is a cross-sectional view along the line XIV-XIV in FIG. 9. FIG. 15 is a cross-sectional view along the line XV-XV in FIG. 13. FIG. 16A is a cross-sectional view along the line XVIA-XVIA in FIG. 9. In FIGS. 7 and 9, for clarity, connecting lines 80 are depicted with a hatching pattern (same applies to FIG. 16D described later).

With reference to FIGS. 6 and 7, one diode group 9 includes the plurality of diodes D connected in series in the reverse direction. The reverse direction voltages of the plurality of diodes D included in one diode group 9 are equal. The number of diodes D included in one diode group 9 is 12 in this embodiment. The number of diodes D included in one diode group 9 is merely one example, and the number of diodes D may differ. The diodes D included in the diode group 9 may be referred to as “clamp diodes.” As described above, the cathode of the diode group 9 is connected to the drain terminal 15. The anode of the diode group 9 is connected to the gate control circuit 24 (FIG. 5A) or the ground terminal 14a (FIG. 5B). Among the plurality of diodes D connected in series, the diode D closest to the cathode is sometimes referred to as a drain-side diode DD. Among the plurality of diodes D connected in series, the diode D closest to the anode is sometimes referred to as a ground-side diode element DG (control terminal diode element).

Among the diode group 9 included in the active clamp circuit 30 (FIG. 5A) and the diode group 9 included in the voltage clamp circuit 35 (FIG. 5B), the numbers of diodes D included in the respective diode groups 9 may differ therebetween. Among the diode group 9 included in the active clamp circuit 30 and the diode group 9 included in the voltage clamp circuit 35, the reverse direction voltages of the diodes D may differ therebetween.

The plurality of diodes D are formed in the diode formation region 8 set in the first main surface 3 of the control region 7. In this embodiment, the diode formation region 8 has a belt shape along the first direction X. In this embodiment, there is one diode formation region 8. The diode formation region 8 may a belt shape along the second direction Y. The diode formation region 8 is delineated by a trench separation structure 60. The number of trench separation structures 60 is one.

The trench separation structure 60 surrounds the periphery of the plurality of diodes D. The trench separation structure 60 electrically isolates the plurality of diodes D from other regions in the control region 7. The trench separation structure 60 may be referred to as a “region separation structure,” a “deep trench isolation (DTI) structure,” or an “inner separation structure.”

With reference to FIGS. 11, 12, and 14, the trench separation structure 60 includes a separation trench 61, a separation insulating layer 62, and a separation electrode 63. In other words, the trench separation structure 60 has a single electrode structure including one electrode embedded in the separation trench 61 with an insulator interposed therebetween.

The separation trench 61 is formed downward from the first main surface 3 towards the second main surface 4. The separation trench 61 is formed on the first main surface 3 side at a gap from the bottom of the drift region 11. The separation insulating layer 62 covers the wall surface of the separation trench 61. The separation insulating layer 62 may include a silicon oxide film. The separation insulating layer 62 may include a silicon oxide film made from an oxide of the chip 2, or may include a silicon oxide film formed by CVD. The separation electrode 63 is embedded in the separation trench 61 with the separation insulating layer 62 therebetween. The separation electrode 63 may include conductive polysilicon.

The trench separation structure 60 has a trench width WT and a trench depth DT. The trench width WT is a width in a direction perpendicular to the direction of extension of the trench separation structure 60. An aspect ratio DT/WT of the trench separation structure 60 may exceed 1 and be 5 or less. The aspect ratio DT/WT is the ratio of the trench depth DT to the trench width WT. It is preferable that the aspect ratio DT/WT be 2 or greater. It is preferable that the bottom wall of the trench separation structure 60 be disposed at a gap of 1 μm to 5 μm, inclusive, from the bottom of the drift region 11.

With reference to FIGS. 8 and 9, the trench separation structure 60 has corners that connect portions extending in the first direction X and the second direction Y with an arc shape (curved shape). In this embodiment, the four corners of the trench separation structure 60 are formed in an arc shape. It is preferable that the corners of the trench separation structure 60 have a constant trench width WT along the arc direction.

With reference to FIG. 11 and the like, the separation trench 61 includes a side wall and a bottom wall. The angle formed between the side wall of the separation trench 61 and the first main surface 3 in the chip 2 may be 90° to 92°, inclusive. The separation trench 61 may be formed in a tapered shape whereby the opening width narrows from the opening to the bottom wall. It is preferable that the bottom wall corner of the separation trench 61 be formed in a curved shape. The entirety of the bottom wall of the separation trench 61 may be formed so as to curve towards the second main surface 4.

The separation insulating layer 62 is formed on the wall surface of the separation trench 61. The separation insulating layer 62 specifically is formed as a film on the entire wall surface of the separation trench 61, and delineates a recess space in the separation trench 61. It is preferable that the separation insulating layer 62 include a silicon oxide film. It is particularly preferable that the separation insulating layer 62 include a silicon oxide film made from an oxide of the chip 2.

The separation electrode 63 is embedded as an integrated member in the separation trench 61 with the separation insulating layer 62 therebetween. In this embodiment, the separation electrode 63 includes conductive polysilicon. The source potential is applied to the separation electrode 63. The separation electrode 63 has an electrode surface (separation electrode surface) exposed from the separation trench 61. The electrode surface of the separation electrode 63 may be recessed in a curved shape towards the bottom wall of the separation trench 61. It is preferable that the electrode surface of the separation electrode 63 be at a gap from the first main surface 3 towards the bottom wall of the separation trench 61 in the depth direction of the separation trench 61.

With reference to FIGS. 11, 12, 14, and 16A, in the diode formation region 8, a first well region 64 (first impurity region) is formed in the surface layer of the first main surface 3. The first well region 64 is a p-type (first conductivity type) impurity region formed in the surface layer of the drift region 11 in the diode formation region 8. The first well region 64 extends as a layer along the first main surface 3.

The first well region 64 is formed shallower than the trench separation structure 60, and has a bottom positioned further towards the first main surface 3 than the bottom wall of the trench separation structure 60. It is preferable that the bottom of the first well region 64 be positioned further towards the second main surface 4 than an intermediate section of the depth range of the trench separation structure 60.

The first well region 64 is in contact with the trench separation structure 60 in the outer periphery of the diode formation region 8. In this embodiment, the first well region 64 is not formed in a region outside the trench separation structure 60.

With reference to FIGS. 14 to 16A, in this embodiment, the plurality of diodes D are formed in the surface layer of the first well region 64. In this embodiment, the plurality of diodes D are all Zener diodes. More specifically, the plurality of diodes D are all driftless Zener diodes. In this embodiment, the plurality of diodes D are arrayed in a belt shape along the first direction X. One of the diodes D will be explained below.

With reference to FIGS. 11, 12, and 14 to 16A, one diode D includes an n-type well region 66 (second impurity region) formed in the surface layer of the first well region 64, and a cathode region 67 and an anode region 68 that are formed in the surface layer of the n-type well region 66. A plurality of the n-type well regions 66 are formed with a gap therebetween in the first direction X.

One diode D includes the n-type well region 66 formed in the surface layer of the first well region 64, and an n-type cathode region 67 and a p-type anode region 68 that are formed in the surface layer of each n-type well region 66.

As will be described next, in this embodiment, the anode region 68 has a quadrilateral shape with long sides in a plan view. Below, the lengthwise direction of the anode region 68 is referred to as a first element direction X1 and a direction perpendicular to the first element direction X1 is referred to as a second element direction Y1. In this embodiment, the first element direction X1 and the second element direction Y1 match the first direction X and the second direction Y, respectively.

The n-type well region 66 includes a second well region 69 (first concentration region) and a third well region 70 (second concentration region). The second well region 69 is an n-type (second conductivity type) impurity region formed in the surface layer of the first well region 64. The second well region 69 extends as a layer along the first main surface 3.

The second well region 69 is formed away, towards the inside, from the trench separation structure 60. The outer peripheral edge of the second well region 69 has a constant depth. The bottom of the second well region 69 may be formed in a region towards the first main surface 3 in relation to the intermediate section of the trench separation structure 60.

With reference to FIGS. 10 and 13, the second well region 69 is a quadrilateral having peripheral edges along the first element direction X1 and the second element direction Y1 in a plan view. A distance L2 (FIG. 10) and a distance L22 (FIG. 13) in the first element direction X1 of the second well region 69 are respectively longer than a distance L12 (FIG. 10) and a distance L32 (FIG. 13) in the second element direction Y1 of the second well region 69.

With reference to FIGS. 11, 12, and 14 to 16A, the third well region 70 is an n-type impurity region formed in the surface layer of the second well region 69. The third well region 70 has an n-type impurity concentration higher than that of the second well region 69.

The third well region 70 extends as a layer along the first main surface 3. The third well region 70 is formed away, towards the inside, from the trench separation structure 60. The third well region 70 is formed away, towards the inside, from the first well region 64. The outer peripheral edge of the third well region 70 has a constant depth.

The bottom of the third well region 70 may be formed in a region towards the first main surface 3 in relation to the intermediate section of the trench separation structure 60.

With reference to FIGS. 10 and 13, the third well region 70 is a quadrilateral having peripheral edges along the first element direction X1 and the second element direction Y1 in a plan view. A distance L3 (first distance, FIG. 10) and a distance L23 (second distance, FIG. 13) in the first element direction X1 of the third well region 70 are respectively longer than a distance L13 (FIG. 10) and a distance L33 (FIG. 13) in the second element direction Y1 of the third well region 70.

With reference to FIGS. 11, 12, and 14 to 16A, the third well region 70 is formed away, towards the inside and towards the first main surface 3 side, from the first well region 64. In other words, the second well region 69 not only covers the bottom of the third well region 70 from below, but surrounds the periphery of the third well region 70. In other words, the second well region 69 has a surrounding section 69a that surrounds the sides of the third well region 70.

With reference to FIGS. 10 and 13, the surrounding section 69a surrounds the entire outer periphery of the third well region 70. The surrounding section 69a is exposed at the first main surface 3. The surrounding section 69a has a width W1 and a width W21 in the first element direction X1. The surrounding section 69a has a width W11 and a width W31 in the second element direction Y1. The widths W1, W11, W21, and W31 are constant in the depth direction.

In this embodiment, there is one each of the cathode region 67 and the anode region 68 included in each diode D. In this embodiment, the cathode region 67 surrounds the anode region 68 in a loop. There may be a plurality of the cathode region 67 and/or the anode region 68.

With reference to FIGS. 11, 12, and 14 to 16A, the cathode region 67 and the anode region 68 is formed in the surface layer of the third well region 70. The cathode region 67 and the anode region 68 are not formed in the surface layer of the second well region 69. The cathode region 67 and the anode region 68 are in contact with the surface layer of the third well region 70. The cathode region 67 and the anode region 68 form a pn junction by sandwiching a portion of the third well region 70.

In this embodiment, the cathode region 67 and the anode region 68 are formed in the surface layer of the third well region 70 with a gap in both the first element direction X1 and the second element direction Y1.

The anode region 68 is exposed at the first main surface 3. The anode region 68 has a p-type impurity concentration higher than that of the first well region 64. As described above, the anode region 68 has a quadrilateral shape with long sides in the first element direction X1 in a plan view. The peripheral edges of the anode region 68 are formed along the first element direction X1 and the second element direction Y1.

The cathode region 67 is exposed at the first main surface 3. The cathode region 67 has an n-type impurity concentration higher than that of the third well region 70. The cathode region 67 is formed as a quadrilateral loop along the first element direction X1 and the second element direction Y1. The cathode region 67 surrounds the periphery of the anode region 68. In this embodiment, the cathode region 67 surrounds the entire outer periphery of the anode region 68.

With reference to FIGS. 10 and 13, the anode region 68 has a width W3 (FIG. 10) and a width W23 (FIG. 13) in the first element direction X1. The anode region 68 has a width W13 (FIG. 10) and a width W33 (FIG. 13) in the second element direction Y1. The widths W3 and W23 are greater than the widths W13 and W33. The widths W3 and W23 may respectively be equal to the widths W13 and W33, or less than the widths W13 and W33.

The cathode region 67 has a width W4 (FIG. 10) and a width W24 (FIG. 13) in the first element direction X1. The cathode region 67 has a width W14 and a width W34 in the second element direction Y1. In this embodiment, the widths W4 and W24 are less than the widths W14 and W34. The widths W4 and W24 may respectively be equal to the widths W14 and W34, or less than the widths W14 and W34.

In other words, the cathode region 67 and the anode region 68 sandwich a portion of the third well region 70 and oppose each other in the first element direction X1 and the second element direction Y1.

The gap between the cathode region 67 and the anode region 68 in the first element direction X1 is a gap W5 (FIG. 10) and a gap W25 (FIG. 13). The gap between the cathode region 67 and the anode region 68 in the second element direction Y1 is a gap W15 (FIG. 10) and a gap W35 (FIG. 13).

In this embodiment, the widths W5 and W25 are equal to the gaps W15 and W35, respectively. The gaps W5 and W25 may respectively be greater than the gaps W15 and W35, or be less than the gaps W15 and W35.

In each diode D, a cathode potential is applied to the cathode region 67 and an anode potential is applied to the anode region 68. The third well region 70 is at the same potential as the cathode region 67. Thus, in each diode D, the third well region 70 is at the cathode potential.

With reference to FIG. 8, the semiconductor device 1 further includes a plurality of p-type guard ring regions 71 exposed at the first main surface 3. The plurality of guard ring regions 71 have a belt shape that extends along the first direction X (first element direction X1) and the second direction Y (second element direction Y1).

In this embodiment, the plurality of guard ring regions 71 include a first guard ring region 72 and a plurality of second guard ring regions 73. The first guard ring region 72 and the plurality of second guard ring regions are connected to each other. Thus, the plurality of second guard ring regions 73 are at the same potential as the first guard ring region 72.

With reference to FIGS. 11 and 14, the first guard ring region 72 is formed in the surface layer of the outer periphery of the first well region 64. The first guard ring region 72 is exposed at the first main surface 3. The first guard ring region 72 has a p-type impurity concentration higher than that of the first well region 64. The first guard ring region 72 may have a p-type impurity concentration equal to the n-type impurity concentration of the cathode region 67.

With reference to FIGS. 8, 10, and 13, the first guard ring region 72 is formed in a loop that follows the trench separation structure 60 in a plan view. The first guard ring region 72 is formed at a gap, towards the inside, from the trench separation structure 60. The first guard ring region 72 has a belt shape that extends along the first direction X (first element direction X1) and the second direction Y (second element direction Y1).

The first guard ring region 72 has two linear sections that extend in the first direction X (first element direction X1). The two linear sections of the first guard ring region 72 sandwich the plurality of diodes D in the second element direction Y1.

In other words, one diode D opposes the two linear sections of the first guard ring region 72 in the second element direction Y1. The gaps between the one diode D and the first guard ring region 72 are a gap W12 (first gap, FIG. 10) and a gap W32 (second gap, FIG. 13).

With reference to FIGS. 12, 15, and 16A, the plurality of second guard ring regions 73 are formed in the surface layer of the first well region 64. The plurality of second guard ring regions 73 are exposed at the first main surface 3.

The plurality of second guard ring regions 73 have a p-type impurity concentration higher than that of the first well region 64. It is preferable that the plurality of second guard ring regions 73 have a p-type impurity concentration equal to that of the first guard ring region 72.

The plurality of second guard ring region 73 may have a p-type impurity concentration equal to the n-type impurity concentration of the cathode region 67.

The plurality of second guard ring regions 73 are respectively sandwiched between two opposing diodes D. The plurality of second guard ring regions 73 have a belt shape extending in a direction intersecting with (perpendicular to) the direction in which the two diodes D oppose each other.

In this embodiment, the second guard ring region 73 is sandwiched in the first element direction X1 by two diodes D adjacent to each other in the first direction X. In this embodiment, there is one second guard ring region 73 sandwiched between the two diodes D. There may alternatively be two or more second guard ring regions 73 sandwiched between the two diodes D.

In this embodiment, the plurality of second guard ring regions 73 are formed in a belt shape extending in the second element direction Y1 between the two diodes D opposing each other in the first element direction X1. Both ends of each second guard ring region 73 in the second element direction Y1 are connected to the first guard ring region 72.

Thus, in this embodiment, one diode D is surrounded by the two linear sections of the first guard ring region 72 and the two second guard ring regions 73.

In other words, one diode D opposes the two linear sections of the first guard ring region 72 in the second element direction Y1. The gaps between the one diode D and the first guard ring region 72 are a gap W12 (FIG. 10) and a gap W32 (FIG. 13).

In other words, one diode D opposes the second guard ring region 73 in the first element direction X1. The gaps between the one diode D and the second guard ring region 73 are a gap W2 (FIG. 10) and a gap W22 (FIG. 13).

With reference to FIGS. 11, 12, and 14 to 16A, the semiconductor device 1 includes a plurality of inner separation structures 74 and a plurality of outer separation structures 75 that selectively cover the first main surface 3 in the diode formation region 8.

The plurality of inner separation structures 74 and the plurality of outer separation structures 75 are provided in a one-to-one relationship with the plurality of diodes D. Each outer separation structure 75 surrounds the outside of a corresponding inner separation structure 74.

One of the inner separation structures 74 will be explained here. The inner separation structure 74 is formed in a loop shape. A region that exposes the anode region 68 is formed inside the inner separation structure 74. Thus, the inner periphery of the inner separation structure 74 delineates the outer periphery of the anode region 68.

A region that exposes the cathode region 67 is formed outside the inner separation structure 74. Thus, the outer periphery of the inner separation structure 74 delineates the inner periphery of the cathode region 67.

One of the outer separation structures 75 will be explained here. The outer separation structure 75 is formed in a loop surrounding the inner separation structure 74. A region that exposes the cathode region 67 is formed inside the outer separation structure 75. Thus, the inner periphery of the outer separation structure 75 delineates the outer periphery of the cathode region 67.

With reference to FIG. 16A, a region that exposes the second guard ring region 73 is formed by two adjacent outer separation structures 75. In this embodiment, a region that exposes the second guard ring region 73 is formed by two outer separation structures 75 that are adjacent to each other in the first element direction X1 (first direction X). Thus, the two outer separation structures 75 that are adjacent to each other in the first element direction X1 (first direction X) delineate the edges of the second guard ring region 73 in the first element direction X1 (first direction X).

With reference to FIG. 12, the semiconductor device 1 includes a main surface insulating layer 76 that selectively covers the first main surface 3 in the control region 7. The main surface insulating layer 76 may include a silicon oxide film. It is preferable that the main surface insulating layer 76 include a silicon oxide film made from an oxide of the chip 2. The main surface insulating layer 76 is not formed in the diode formation region 8.

With reference to FIGS. 11, 12, and 14, the semiconductor device 1 includes a field insulating layer 77 that selectively covers the first main surface 3 in the control region 7. The field insulating layer 77 is thicker than the main surface insulating layer 76. The field insulating layer 77 may have substantially the same thickness of the separation insulating layer 62. The field insulating layer 77 may include a silicon oxide film. The field insulating layer 77 may include a silicon oxide film made from an oxide of the chip 2, or may include a silicon oxide film formed by CVD.

The field insulating layer 77 covers the first main surface 3 along the inner wall of the trench separation structure 60 in the control region 7, and is connected to the main surface insulating layer 76. The field insulating layer 77 covers the first main surface 3 along the outer wall of the trench separation structure 60 outside the control region 7, and is integrally connected to the separation insulating layer 62. The field insulating layer 77 is lead out from the separation trench 61 in the horizontal direction along the first main surface 3.

A region where the first guard ring region 72 is exposed is formed inside the field insulating layer 77. In other words, a region that exposes the first guard ring region 72 is formed by the field insulating layer 77 and the outer separation structures 75.

With reference to FIGS. 11, 12, and 14 to 16A, the aforementioned interlayer insulating layer 12 covers the trench separation structure 60, the cathode region 67, the anode region 68, the first guard ring region 72, the second guard ring region 73, the inner separation structure 74, and the outer separation structure 75 in the control region 7.

The interlayer insulating layer 12 is formed from an insulator such as silicon oxide or silicon nitride, for example. The interlayer insulating layer 12 may be an undoped silica glass (HDP-USG: high density plasma CVD-undoped silica glass) film formed by high density plasma CVD. The interlayer insulating layer 12 may include a plurality of insulating layers. The plurality of insulating layers may be segmented on the basis of tiers of wiring layers formed on the main surface. For example, a configuration may be adopted in which an insulating layer in which a first wiring layer with a multilayer wiring structure is formed inside the interlayer insulating layer 12 is a first insulating layer, and an insulating layer in which a second wiring layer is formed is a second insulating layer.

In this embodiment, the semiconductor device 1 includes a first wiring layer 78 disposed in the interlayer insulating layer 12. The first wiring layer 78 is formed on the first insulating layer 79. The first wiring layer 78 includes a connective wiring line 80 to be described below.

With reference to FIG. 9, the semiconductor device 1 includes a plurality of the connective wiring lines 80 that connect two adjacent diodes D in series. In this embodiment, one connective wiring line 80 includes two cathode wiring lines 81 and one anode wiring line 82. The two cathode wiring lines 81 and the one anode wiring line 82 are connected to each other.

With reference to FIGS. 8 and 9, the semiconductor device 1 includes a plurality of first plug electrodes 83, a plurality of second plug electrodes 84, a plurality of third plug electrodes 85 (FIG. 8), and a plurality of fourth plug electrodes 86 (FIGS. 11 and 14). The first plug electrodes 83, the second plug electrodes 84, the third plug electrodes 85, and the fourth plug electrodes 86 are all embedded in the interlayer insulating layer 12.

The plurality of first plug electrodes 83 and the plurality of second plug electrodes 84 correspond to each diode D.

With reference to FIGS. 11, 14, and the like, the first plug electrode 83 transmits the cathode potential to the cathode region 67 of the corresponding diode D. The cathode wiring line 81 of the connective wiring line 80 is connected to the top end of the first plug electrode 83. The cathode wiring line 81 of the connective wiring line 80 is electrically connected to the cathode region 67 of the corresponding diode D via the first plug electrode 83.

The first plug electrode 83 may be formed to be triangular, quadrilateral, rectangular, polygonal, circular, or elliptical in a plan view. Of course, the first plug electrode 83 may be formed in a belt shape (e.g., rectangle) extending in the first element direction X1 or the second element direction Y1.

The second plug electrode 84 transmits the anode potential to the anode region 68 of the corresponding diode D. The anode wiring line 82 of the connective wiring line 80 is connected to the top end of the second plug electrode 84. The anode wiring line 82 of the connective wiring line 80 is electrically connected to the anode region 68 of the corresponding diode D via the second plug electrode 84.

The second plug electrode 84 may be formed to be triangular, quadrilateral, rectangular, polygonal, circular, or elliptical in a plan view. Of course, the second plug electrode 84 may be formed in a belt shape (e.g., rectangle) extending in the first element direction X1 or the second element direction Y1.

The plurality of third plug electrodes 85 transmit the ground potential to the first guard ring region 72. The plurality of fourth plug electrode 86 transmit the ground potential to the trench separation structure 60.

The third plug electrodes 85 and the fourth plug electrodes 86 may be formed to be triangular, quadrilateral, rectangular, polygonal, circular, or elliptical in a plan view. Of course, the third plug electrodes 85 and the fourth plug electrodes 86 may be formed in a belt shape (e.g., rectangle) extending in the first element direction X1 or the second element direction Y1.

With reference to FIGS. 11 and 14, the separation electrode 63 of the trench separation structure 60 has applied thereto the ground potential from a ground line 87 via the fourth plug electrode 86. The ground line 87 is electrically connected to the first guard ring region 72 via the third plug electrode 85. As a result, the ground potential is applied to the guard ring region 71.

Also, as described above, the first guard ring region 72 and the plurality of second guard ring regions are connected to each other, and the plurality of second guard ring regions 73 are at the same potential as the first guard ring region 72. As a result, the ground potential is also applied to the second guard ring region 73. As a result of ground potential being applied to the first guard ring region 72 and the plurality of second guard ring regions 73, the first well region 64 is fixed at ground potential.

With reference to FIG. 12, a drain-side connective wiring line 80A connected to a first diode D1 (drain-side diode DD) furthest toward the drain terminal 15 includes one cathode wiring line 81, and a plurality of terminal plug electrodes 90 that electrically connect the cathode wiring line 81 to the drift region 11.

The control region 7 includes a terminal plug arrangement region 91 adjacent to the diode formation region 8 on one side in the first direction X, with the trench separation structure 60 therebetween. The terminal plug arrangement region 91 is a region that is insulated from the diode formation region 8. In the terminal plug arrangement region 91, the first main surface 3 is selectively covered by the main surface insulating layer 76. The terminal plug arrangement region 91 is a region that is insulated from the control region 7 on the first main surface 3. That is, the terminal plug arrangement region 91 may be a region that is insulated from both the diode formation region 8 and the control region 7.

In the terminal plug arrangement region 91, an n-type high concentration region 92 is formed in the surface layer of the first main surface 3. The high concentration region 92 is exposed at the first main surface 3. The n-type impurity concentration of the high concentration region 92 is higher than the n-type impurity concentration of the first well region 64.

The top ends of the plurality of terminal plug electrodes 90 are in contact with the bottom surface of the drain-side connective wiring line 80A. The bottom ends of the plurality of terminal plug electrodes 90 pass through the main surface insulating layer 76 to connect to the high concentration region 92 exposed at the first main surface 3. In other words, the plurality of terminal plug electrodes 90 are connected to both the cathode wiring line 81 and the drift region 11. As a result, the anode wiring line 82 is electrically connected to the drift region 11 via the plurality of terminal plug electrodes 90.

The drift region 11 is electrically connected to both the drain region 10 and the drain terminal 15. Thus, the drain-side connective wiring line 80A is electrically connected to the drain terminal 15 via the drift region 11 and the drain region 10. As a result, a power source potential is applied to the drain-side connective wiring line 80A.

With reference to FIGS. 6 and 7, the plurality of diodes D include at least one first diode D1 and at least one second diode D2. The second diode D2 has a shorter outer periphery than the first diode D1. The first diode D1 and the second diode D2 have the same configuration as each other aside from the length of the outer periphery.

The first diode D1 and the second diode D2 have the same reverse direction voltage as each other. As an example, the reverse direction voltage is approximately 5.4V for both the first diode D1 and the second diode D2. Of course, the reverse direction voltage of the first diode D1 and the second diode D2 is not limited to this example.

The second diode D2 has lower element withstand voltage than that of the first diode D1. The element withstand voltages of the first diode D1 and the second diode D2 may be referred to as the “guaranteed withstand voltage.” The element withstand voltages of the first diode D1 and the second diode D2 are inter-well withstand voltages between the third well region 70 (n-type well region 66) and the first well region 64 included in the first diode D1 and the second diode D2.

The ratio of the element withstand voltage of the second diode D2 to the element withstand voltage of the first diode D1 may be 0.3 or greater and less than 1.0. It is preferable that the ratio of the element withstand voltages be 0.7 to 0.9, inclusive. As an example, the element withstand voltages are approximately 70V and 55V for the first diode D1 and the second diode D2, respectively. Of course, the element withstand voltages of the first diode D1 and the second diode D2 are not limited to this example.

A plurality of the second diodes D2 may be provided. A plurality of the first diodes D1 may be provided. The first diodes D1 may be connected to the drain terminal 15 side of all of the second diodes D2. The first diodes D1 may be fewer in number than the second diodes D2.

In this embodiment, among 12 diodes D connected in series, the two diodes D closest to the drain terminal 15 are the first diodes D1. The drain-side diode DD is the first diode D1.

Among the 12 diodes D connected in series, the 10 diodes D on the side opposite to the drain terminal 15 are the second diodes D2. The ground-side diode DG is the second diode D2.

The difference in dimensions between the first diode D1 and the second diode D2 will be described in detail below.

With reference to FIGS. 10 and 13, a distance L21 (second distance, FIG. 13) in the first element direction X1 of the outer periphery of the second diode D2 is shorter than a distance L1 (first distance, FIG. 10) in the first element direction X1 of the outer periphery of the first diode D1 (L21<L1). The distance ratio (L21/L1) of the distance L21 to the distance L1 may be 0.1 to 1.0, inclusive. It is preferable that the distance ratio (L21/L1) be 0.3 to 1.0, inclusive.

A distance L31 (FIG. 13) in the second element direction Y1 of the outer periphery of the second diode D2 is shorter than a distance L1 (FIG. 10) in the second element direction Y1 of the outer periphery of the first diode D1 (L31<L11). The distance ratio (L31/L11) of the distance L31 to the distance L11 may be 0.1 to 1.0, inclusive. It is preferable that the distance ratio (L31/L11) be 0.3 to 1.0, inclusive.

A distance L22 (FIG. 13) in the first element direction X1 of the outer periphery of the second well region 69 in the second diode D2 is shorter than a distance L2 (FIG. 10) in the first element direction X1 of the outer periphery of the second well region 69 in the first diode D1 (L22<L2). The distance ratio (L22/L2) of the distance L22 to the distance L2 may be 0.1 to 1.0, inclusive. It is preferable that the distance ratio (L22/L2) be 0.3 to 1.0, inclusive.

A distance L32 (FIG. 13) in the second element direction Y1 of the outer periphery of the second well region 69 in the second diode D2 is shorter than a distance L12 (FIG. 10) in the second element direction Y1 of the outer periphery of the second well region 69 in the first diode D1 (L32/L12). The distance ratio (L32/L12) of the distance L32 to the distance L12 may be 0.1 to 1.0, inclusive. It is preferable that the distance ratio (L32/L12) be 0.3 to 1.0, inclusive.

A gap W22 (fourth gap, FIG. 13) in the first element direction X1 between the outer periphery of the second well region 69 in the second diode D2 and the guard ring region 71 is narrower than a gap W2 (third gap, FIG. 10) in the first element direction X1 between the outer periphery of the second well region 69 in the first diode D1 and the second guard ring region 73 (W22<W2). A gap ratio (W22/W2) of the gap W22 to the gap W2 may be 0.1 to 2.0, inclusive. It is preferable that the gap ratio (W22/W2) be 0.3 to 1.0, inclusive.

A gap W32 (FIG. 13) in the second element direction Y1 between the outer periphery of the second well region 69 in the second diode D2 and the guard ring region 71 is narrower than a gap W12 (FIG. 10) in the second element direction Y1 between the outer periphery of the second well region 69 in the first diode D1 and the second guard ring region 73 (W32<W12). A gap ratio (W32/W12) of the gap W32 to the gap W12 may be 0.1 to 2.0, inclusive. It is preferable that the gap ratio (W32/W12) be 0.3 to 1.0, inclusive.

A distance L23 (fourth distance, FIG. 13) in the first element direction X1 of the outer periphery of the third well region 70 in the second diode D2 is shorter than a distance L3 (third distance, FIG. 10) in the first element direction X1 of the outer periphery of the third well region 70 in the first diode D1 (L23<L3). The distance ratio (L23/L3) of the distance L23 to the distance L3 may be 0.1 to 1.0, inclusive. It is preferable that the distance ratio (L23/L3) be 0.3 to 1.0, inclusive.

A distance L33 (FIG. 13) in the second element direction Y1 of the outer periphery of the third well region 70 in the second diode D2 is shorter than a distance L13 (FIG. 10) in the second element direction Y1 of the outer periphery of the third well region 70 in the first diode D1 (L33<L13). The distance ratio (L33/L13) of the distance L33 to the distance L13 may be 0.1 to 1.0, inclusive. It is preferable that the distance ratio (L33/L13) be 0.3 to 1.0, inclusive.

A width W21 (second width, FIG. 13) in the first element direction X1 of the surrounding section 69a in the second diode D2 is narrower than a width W1 (first width, FIG. 10) in the first element direction X1 of the surrounding section 69a in the first diode D1 (W21<W1). A width ratio (W21/W1) of the width W21 to the width W1 may be 0.1 to 0.8, inclusive. It is preferable that width ratio (W21/W1) be 0.2 to 0.6, inclusive.

A width W31 (FIG. 13) in the second element direction Y1 of the surrounding section 69a in the second diode D2 is narrower than a width W11 (FIG. 10) in the second element direction Y1 of the surrounding section 69a in the first diode D1 (W31<W11). A width ratio (W31/W11) of the width W31 to the width W11 may be 0.1 to 0.8, inclusive. It is preferable that width ratio (W31/W11) be 0.2 to 0.6, inclusive.

A width W23 (FIG. 13) of a gap in the first element direction X1 of the anode region 68 in the second diode D2 is narrower than a width W3 (FIG. 10) in the first element direction X1 of the anode region 68 in the first diode D1 (W23<W3). The width W23 may be the same as the width W3. A width ratio (W23/W3) of the width W23 to the width W3 may be 0.1 to 1.0, inclusive. It is preferable that width ratio (W23/W3) be 0.3 to 1.0, inclusive.

A width W33 (FIG. 13) of a gap in the second element direction Y1 of the anode region 68 in the second diode D2 is narrower than a width W13 (FIG. 10) in the second element direction Y1 of the anode region 68 in the first diode D1 (W33<W13). The width W33 may be the same as the width W13. A width ratio (W33/W13) of the width W33 to the width W13 may be 0.1 to 1.0, inclusive. It is preferable that width ratio (W33/W13) be 0.3 to 1.0, inclusive.

A width W24 (FIG. 13) of a gap in the first element direction X1 of the cathode region 67 in the second diode D2 is narrower than a width W4 (FIG. 10) in the first element direction X1 of the cathode region 67 in the first diode D1 (W24<W4). The width W24 may be the same as the width W4. A width ratio (W24/W4) of the width W24 to the width W4 may be 0.1 to 1.0, inclusive. It is preferable that width ratio (W24/W4) be 0.3 to 1.0, inclusive.

A width W34 (FIG. 13) of a gap in the second element direction Y1 of the cathode region 67 in the second diode D2 is narrower than a width W14 (FIG. 10) in the second element direction Y1 of the cathode region 67 in the first diode D1 (W34<W14). The width W34 may be the same as the width W14. A width ratio (W34/W14) of the width W34 to the width W14 may be 0.1 to 1.0, inclusive. It is preferable that width ratio (W34/W14) be 0.3 to 1.0, inclusive.

A gap W25 (FIG. 13) in the first element direction X1 of the cathode region 67 and the anode region 68 in the second diode D2 is narrower than a gap W5 (FIG. 10) in the first element direction X1 of the cathode region 67 and the anode region 68 in the first diode D1 (W25<W5). The gap W25 may be the same as the gap W5. A width ratio (W25/W5) of the width W25 to the width W5 may be 0.1 to 1.0, inclusive. It is preferable that width ratio (W25/W5) be 0.3 to 1.0, inclusive.

A gap W35 (FIG. 13) in the second element direction Y1 of the cathode region 67 and the anode region 68 in the second diode D2 is narrower than a gap W15 (FIG. 10) in the second element direction Y1 of the cathode region 67 and the anode region 68 in the first diode D1 (W35<W15). The gap W35 may be the same as the gap W15. A width ratio (W35/W15) of the width W35 to the width W15 may be 0.1 to 1.0, inclusive. It is preferable that width ratio (W35/W15) be 0.3 to 1.0, inclusive.

With reference to FIG. 8, the two adjacent first diodes D1 oppose each other in the first direction X (first element direction X1) with a gap W6 therebetween. The two adjacent second diodes D2 oppose each other in the first direction X (first element direction X1) with a gap W26 therebetween. The gap W26 is narrower than the gap W6 (W26<W6). A width ratio (W26/W6) of the width W26 to the width W6 may be 0.1 to 2.0, inclusive. It is preferable that width ratio (W26/W6) be 0.3 to 1.0, inclusive.

As described above, in this embodiment, one diode D is surrounded by the two linear sections of the first guard ring region 72 and the two second guard ring regions 73. In this specification, the one diode D, the guard ring region 71 surrounding the diode D (two linear sections of first guard ring region 72 and two second guard ring regions 73), and the region between the outer periphery of the one diode D and the outer periphery of the guard ring region 71 in the surface layer of the first main surface 3 are collectively referred to as one diode element DS.

The guard ring region 71 (the two linear sections of the first guard ring region 72 and the two second guard ring regions 73) form an element boundary B (FIG. 8) on the first main surface 3 in a plan view, and delineate the diode element DS.

The diode element DS will be explained below.

With reference to FIGS. 6 and 7, the semiconductor device 1 includes a plurality (e.g., 12) of diode elements DS aligned in the first direction X. The two diode elements DS adjacent to each other in the first direction X are in contact with each other. That is, the two adjacent diode elements DS share an element boundary B (FIG. 8) with each other.

The plurality of diode elements DS include at least one first diode element DS1 and at least one second diode element DS2. The outer peripheral distance of one second diode element DS2 is shorter than one first diode element DS1.

With reference to FIGS. 8 and 10, one first diode element DS1 includes one first diode D1, the guard ring region 71 surrounding the first diode D1, and the region between the outer periphery of the first diode D1 and the guard ring region 71 in the surface layer of the first main surface 3.

The first diode element DS1 has a quadrilateral shape in a plan view. The two linear sections of the first guard ring region 72 and the two second guard ring regions 73 that surround the first diode D1 constitute four sides (element boundaries B) of the first diode element DS1 in a plan view. The four sides of the first diode element DS1 are formed along both the first element direction X1 and the second element direction Y1.

The first diode element DS1 has a distance L5 in the first element direction X1. The first diode element DS1 has a distance L15 in the second element direction Y1. In this embodiment, the distance L5 is longer than the distance L15 (L5>L15).

The first diode element DS1 is formed at a gap, towards the inside, from the trench separation structure 60.

The two first diode elements DS1 adjacent to each other in the first direction (first element direction X1), are in contact with each other. That is, the two adjacent first diode elements DS1 share an element boundary B with each other.

With reference to FIGS. 8 and 13, one second diode element DS2 includes one second diode D2, the guard ring region 71 surrounding the second diode D2, and the region between the outer periphery of the second diode D2 and the guard ring region 71 in the surface layer of the first main surface 3.

The second diode element DS2 has a quadrilateral shape in a plan view. The two linear sections of the first guard ring region 72 and the two second guard ring regions 73 that surround the second diode D2 constitute four sides (element boundaries B) of the second diode element DS2 in a plan view. The four sides of the second diode element DS2 are formed along both the first element direction X1 and the second element direction Y1.

The second diode element DS2 has a distance L25 in the first element direction X1. The second diode element DS2 has a distance L35 in the second element direction Y1. In this embodiment, the distance L25 is longer than the distance L35 (L25>L35).

A distance L25 (FIG. 13) in the first element direction X1 of the second diode element DS2 is shorter than a distance L5 (FIG. 10) in the first element direction X1 of the first diode element DS1. A distance L35 (FIG. 13) in the second element direction Y1 of the second diode element DS2 is shorter than a distance L15 (FIG. 10) in the second element direction Y1 of the first diode element DS1.

The second diode element DS2 is formed at a gap, towards the inside, from the trench separation structure 60. The gap in the second direction (second element direction Y1) between the second diode element DS2 and the trench separation structure 60 is wider than the gap in the second direction Y (second element direction Y1) between the first diode element DS1 and the trench separation structure 60.

The two second diode elements DS2 adjacent to each other in the first direction X are in contact with each other. That is, the two adjacent second diode elements DS2 share an element boundary B with each other.

With reference to FIG. 16A, the first diode element DS1 and the second diode element DS2 adjacent to each other in the first direction X are in contact with each other. That is, the first diode element DS1 and the second diode element DS2 adjacent to each other share an element boundary B with each other.

The area ratio of the plane area of one first diode element DS1 to that of one second diode element DS2 may be 0.2 to 0.8, inclusive. The area ratio may be 0.3 to 0.6, inclusive. More preferably, the area ratio may be 0.4 to 0.5, inclusive.

With reference to FIG. 6 and the like, if a counter electromotive force is inputted to the item to be protected, the clamp circuit (active clamp circuit 30 and voltage clamp circuit 35) controls the prescribed clamp voltage to protect the item to be protected from the counter electromotive force. The clamp voltage is limited by the reverse direction voltage (BVz) of the diodes D connected in series in the diode group 9 and the number of diodes D.

If, by connecting diodes D with a BVz of 5.4V in series, a clamp voltage of approximately 64.8V can be realized, for example, then the number of diodes D connected in series would be 12.

The cathode potential applied to the 12 diodes D included in the diode group 9 is reduced farther from the drain terminal 15 side (from the drain-side diode DD (FIG. 6, etc.) towards the ground-side diode DG (FIG. 6, etc.)).

FIG. 16B is a schematic diagram showing an electric configuration of the semiconductor device 1.

With reference to FIG. 16B, where the 12 diodes D included in the diode group 9 are labeled “No. 1” to “No. 12” in order from the drain terminal 15, the potentials applied to the 12 diodes D (“No. 1” to “No. 12”) are 64.8V, 59.4V, 54V, 48.6V, 43.2V, 37.8V, 32.4V, 27V, 21.6V, 16.2V, 10.8V, and 5.4V, respectively.

As described above, the plurality of diodes D include, respectively, the plurality of n-type well regions 66, the plurality of cathode regions 67, and the anode region 68, which are formed in the surface layer of the n-type well region 64. In each diode D, the third well region 70 (n-type well region 66) is at the cathode potential.

The plurality of diodes D each require an element withstand voltage that exceeds the cathode potential. The element withstand voltages are inter-well withstand voltages between the third well region 70 (n-type well region 66) and the first well region 64. In this specification, the element withstand voltage of the diode D is referred to as the element withstand voltage of the diode element DS (diode element DS including the diode D).

In this embodiment, the 12 diode elements DS include two first diode elements DS1, and 10 second diode elements DS2 with a shorter outer peripheral distance than the first diode elements DS1. The element withstand voltage of the second diodes DS2 is lower than that of the first diode elements DS1. In the example of FIG. 16B, the element withstand voltages are approximately 70V and 55V for the first diode elements DS1 the second diode elements DS2, respectively.

Among the 12 diode elements DS, the two diode elements DS on the side towards the drain terminal 15 are the first diode elements DS1. That is, the diode elements DS corresponding to the “No. 1” and “No. 2” diodes (sometimes referred to below as the “‘1 No. 1’ and ‘No. 2’ diode elements DS”) are the first diode elements DS1.

The cathode potentials applied to the two diode elements DS are 64.8V and 59.4V, respectively. The element withstand voltage of the first diode elements DS1 is approximately 70V, and thus, the element withstand voltage exceeds the cathode potential. That is, the element withstand voltage required of the “No. 1” and “No. 2” diode elements DS is satisfied.

It would not be preferable to use the second diode elements DS2 for the “No. 1” and “No. 2” diode elements DS. The element withstand voltage of the second diode elements DS2 is approximately 55V, and thus, the element withstand voltage is less than the cathode potential.

Meanwhile, among the 12 diode elements DS, the 10 diode elements DS on the side opposite to the drain terminal 15 are the second diode elements DS2. That is, the diode elements DS corresponding to the 10 diodes “No. 3” to “No. 12” are the second diode elements DS2.

The cathode potentials applied to the 10 diode elements DS are in the range of 5.4V to 54V, inclusive. The element withstand voltage of the second diode elements DS2 is approximately 55V. The element withstand voltage of the second diode elements DS2 exceeds the cathode potentials applied to the “No. 3” to “No. 12” diode elements DS. That is, the element withstand voltage of the second diode elements DS2 satisfies the element withstand voltage required of the “No. 3” and “No. 12” diode elements DS.

In conventional configurations, in order to increase the element withstand voltage of a plurality of diode elements, elements having a high element withstand voltage (high withstand voltage elements) are used for all of the plurality of diode elements.

However, the plane area of the high withstand voltage element is relatively large. This presents the problem that, if high withstand voltage elements are used for all of the plurality of diode elements DS, then the total plane area of all of the plurality of diode elements would increase.

In the semiconductor device 1, the plurality of diode elements DS include at least one first diode element DS1, and at least one second diode element DS2 with a shorter outer peripheral distance than the first diode element DS1. The first diode element DS1 is connected to the drain terminal 15 side of the second diode element DS2.

That is, the first diode element DS1 with a relatively large outer peripheral distance is disposed towards the drain terminal 15. The second diode element DS2 with a relatively short outer peripheral distance is disposed on the side opposite to the drain terminal 15. The element withstand voltage of the diode element DS tends to decrease as the outer peripheral distance shortens. Thus, the second diode element DS2 has a lower element withstand voltage than that of the first diode element DS1.

Only the diode elements DS with a high cathode potential need to be used for the diode elements DS1 with a high element withstand voltage, and there is no need to use diode elements DS with a high element withstand voltage for the diode elements DS with a low cathode potential. The cathode potential applied to the 12 diode elements DS is reduced farther from the drain terminal 15 side.

Thus, if the first diode elements DS1 are used for the diode elements DS closest to the drain terminal 15 among the diode elements DS towards the drain terminal 15, and the second diode elements DS2 are used for some of the other diode elements DS, then the element withstand voltages required for the individual diode elements DS can be satisfied. By using the second diode element DS2, it is possible to reduce the overall plane area of the plurality of diode elements DS.

As a result of the above, it is possible to reduce the plane area of all of the plurality of diode elements DS in the clamp circuits 30 and 35 while satisfying the withstand voltage required of the individual diode elements DS.

In this embodiment, the first diode elements DS1 and the second diode elements DS2 have the same reverse direction voltage as each other. Thus, by connecting in the reverse direction the plurality of diode elements DS having the same reverse direction voltage, it is possible to attain the diode group 9.

Also, in this embodiment, the second diode element DS2 has a lower element withstand voltage than that of the first diode element DS1. That is, the first diode element DS1 with a higher element withstand voltage is disposed towards the drain terminal 15. The second diode element DS2 with a relatively low element withstand voltage is disposed towards the side opposite to the drain terminal 15.

Also, in this embodiment, the first diode element DS1 is connected to the drain terminal 15 side of all of the second diode elements DS2. That is, the first diode element DS1 is not disposed on the side opposite to the drain terminal 15. Thus, it is possible to further reduce the overall plane area of the plurality of diode elements DS.

Also, in this embodiment, the first diode elements DS1 may be fewer in number than the second diode elements DS2. Thus, it is possible to further reduce the overall plane area of the plurality of diode elements DS.

FIG. 16C shows Modification Example 1 in which the layout of the second diode element DS2 has been modified, and corresponds to FIG. 13.

The second diode element DS2 (second diode D2) shown in FIG. 16C differs from the second diode element DS2 (second diode D2) shown in FIG. 13 in terms of the dimensions of the cathode region 67 and the anode region 68. Other components are the same as the second diode element DS2 shown in FIG. 13.

The anode region 68 has a width W63 (fourth width) in the first element direction X1. The anode region 68 has a width W73 in the second element direction Y1. In this embodiment, the width W63 is greater than the width W73. The width W63 may be equal to the width W73, or less than the width W73.

The width W63 is equal to the width W3 (third width, FIG. 10) in the first element direction X1 of the anode region 68 in the first diode D1 (W63=W3). The width W73 is equal to the width W13 (FIG. 10) in the second element direction Y1 of the anode region 68 in the first diode D1 (W73=W13).

The cathode region 67 has a width W64 (sixth width) in the first element direction X1.

The cathode region 67 has a width W74 in the second element direction Y1. In this embodiment, the width W64 is less than the width W74. The width W64 may be equal to the width W74, or greater than the width W74.

The width W64 is equal to the width W4 (fifth width, FIG. 10) in the first element direction X1 of the cathode region 67 in the first diode D1 (W64=W4). The width W74 is equal to the width W14 (FIG. 10) in the second element direction Y1 of the cathode region 67 in the first diode D1 (W74=W14).

The gap (second gap) between the cathode region 67 and the anode region 68 in the first element direction X1 is a gap W65. The gap between the cathode region 67 and the anode region 68 in the second element direction Y1 is a gap W75. The gap W75 is equal to the gap W65. The gap W75 may greater than the gap W65, or be less than the gap W65.

The gap W65 is equal to the gap W5 (first gap, FIG. 10) in the first element direction X1 of the cathode region 67 and the anode region 68 in the first diode D1 (W65=W5). The gap W75 is equal to the gap W15 (FIG. 10) in the second element direction Y1 of the cathode region 67 and the anode region 68 in the first diode D1 (W75=W15).

FIG. 16D shows Modification Example 2 in which the plurality of diode elements DS include a third diode element DS3, and corresponds to FIG. 7. FIG. 16E is a layout view of the first main surface 3 in the third diode element DS3 shown in FIG. 16D.

In Modification Example 2 shown in FIG. 16D, the plurality of diodes D formed in the diode formation region 8 include at least one first diode D1, at least one second diode D2 (first element), and at least one third diode D3 (second element). The third diode D3 has a shorter outer periphery than the second diode D2. The first diode D1, the second diode D2, and the third diode D3 have the same configuration as each other aside from the length of the outer periphery.

The first diode D1, the second diode D2, and the third diode D3 have the same reverse direction voltage as each other. As an example, the reverse direction voltage is approximately 5.4V for the first diode D1, the second diode D2, and the third diode D3.

The third diode D3 has a lower element withstand voltage than the second diode D2. The ratio of the element withstand voltage of the third diode D3 to the element withstand voltage of the second diode D2 may be 0.5 or greater and less than 1.0. If the element withstand voltages are approximately 70V and 55V for the first diode D1 and the second diode D2, respectively, then the element withstand voltage of the third diode D3 is approximately 30V. Of course, the element withstand voltages of the first diode D1, the second diode D2, and the third diode D3 are not limited to this example.

In this embodiment, among 12 diodes D connected in series, the two diodes D closest to the drain terminal 15 are the first diodes D1. Among the 12 diodes D, the five diodes D on the side opposite to the drain terminal 15 are the third diodes D3. The ground-side diode DG is the third diode D3. Among the 12 diodes D, the five diodes D disposed between the first diodes D1 and the third diodes D3 are the second diodes D2.

Modification Example 2 shown in FIG. 16D differs from the embodiment shown in FIG. 6 and the like in that the “No. 8” to “No. 12” diodes among the 10 diodes “No. 3” to “No. 12” are switched from the second diodes D2 to the third diodes D3. The five diodes D “No. 3” to “No. 7” are the second diodes D2, similar to the embodiment shown in FIG. 6 and the like.

With reference to FIG. 16E, a distance L42 in the first element direction X1 of the outer periphery of the second well region 69 in the third diode D3 is shorter than a distance L22 (FIG. 13) in the first element direction X1 of the outer periphery of the second well region 69 in the second diode D2 (L42<L22). A distance L52 in the second element direction Y1 of the outer periphery of the second well region 69 in the third diode D3 is shorter than a distance L32 (FIG. 13) in the second element direction Y1 of the outer periphery of the second well region 69 in the second diode D2 (L52<L32).

A gap W42 in the first element direction X1 between the outer periphery of the second well region 69 in the third diode D3 and the guard ring region 71 is narrower than a gap W22 in the first element direction X1 between the outer periphery of the second well region 69 in the second diode D2 and the second guard ring region 73 (W42<W22). A gap W52 in the second element direction Y1 between the outer periphery of the second well region 69 in the third diode D3 and the guard ring region 71 is narrower than a gap W32 (FIG. 13) in the second element direction Y1 between the outer periphery of the second well region 69 in the second diode D2 and the second guard ring region 73 (W52<W32).

A distance L43 (FIG. 13) in the first element direction X1 of the outer periphery of the third well region 70 in the third diode D3 is shorter than a distance L23 (FIG. 13) in the first element direction X1 of the outer periphery of the third well region 70 in the second diode D2 (L43<L23). A distance L53 in the second element direction Y1 of the outer periphery of the third well region 70 in the third diode D3 is shorter than a distance L33 (FIG. 13) in the second element direction Y1 of the outer periphery of the third well region 70 in the second diode D2 (L53<L33).

A width W41 in the first element direction X1 of the surrounding section 69a in the third diode D3 is narrower than a width W21 (FIG. 13) in the first element direction X1 of the surrounding section 69a in the second diode D2 (W41<W21). A width W51 in the second element direction Y1 of the surrounding section 69a in the third diode D3 is narrower than a width W31 (FIG. 13) in the second element direction Y1 of the surrounding section 69a in the first diode D1 (W51<W31).

A width W43 in the first element direction X1 of the anode region 68 in the third diode D3 is narrower than a width W23 (FIG. 13) in the first element direction X1 of the anode region 68 in the second diode D2 (W43<W23). A width W53 in the second element direction Y1 of the anode region 68 in the third diode D3 is narrower than a width W13 (FIG. 13) in the second element direction Y1 of the anode region 68 in the second diode D2 (W53<W33).

A width W44 in the first element direction X1 of the cathode region 67 in the third diode D3 is narrower than a width W24 (FIG. 13) in the first element direction X1 of the cathode region 67 in the second diode D2 (W44<W24). The gap W44 may be the same as the gap W24. A width W54 in the second element direction Y1 of the cathode region 67 in the third diode D3 is narrower than a width W34 (FIG. 13) in the second element direction Y1 of the cathode region 67 in the second diode D2 (W54<W34). The gap W54 may be the same as the gap W34.

A gap W45 in the first element direction X1 of the cathode region 67 and the anode region 68 in the third diode D3 is narrower than a gap W25 (FIG. 13) in the first element direction X1 of the cathode region 67 and the anode region 68 in the second diode D2 (W45<W25). The gap W45 may be the same as the gap W25. A gap W55 in the second element direction Y1 of the cathode region 67 and the anode region 68 in the third diode D3 is narrower than a gap W35 (FIG. 13) in the second element direction Y1 of the cathode region 67 and the anode region 68 in the second diode D2 (W55<W35). The gap W55 may be the same as the gap W35.

One third diode element DS3 includes one third diode D3, the guard ring region 71 surrounding the third diode D3, and the region between the outer periphery of the third diode D3 and the guard ring region 71 in the surface layer of the first main surface 3.

The third diode element DS3 has a quadrilateral shape in a plan view. The two linear sections of the first guard ring region 72 and the two second guard ring regions 73 that surround the third diode D3 constitute four sides (element boundaries B) of the third diode element DS3 in a plan view. The four sides of the third diode element DS3 are formed along both the first element direction X1 and the second element direction Y1.

A distance L45 in the first element direction X1 of the outer periphery of the third diode D3 is shorter than a distance L25 (FIG. 13) in the first element direction X1 of the outer periphery of the second diode D2 (L45<L25). A distance L55 in the second element direction Y1 of the outer periphery of the third diode element DS3 is shorter than a distance L35 (FIG. 13) in the second element direction Y1 of the outer periphery of the second diode element DS2 (L55<L35).

That is, in Modification Example 2 shown in FIGS. 16D and 16E, the 12 diode elements DS include two first diode elements DS1, five second diode elements DS2, and five third diode elements DS3 with a shorter outer peripheral distance than the second diode elements DS2.

A plurality of the third diode elements DS3 may be provided. The third diode elements DS3 may be disposed to the side opposite the drain terminal 15 of all of the second diode elements DS2. The third diode elements DS3 may be the same in number as the second diode elements DS2. The third diode elements DS3 may be fewer in number than the second diode elements DS2, or may be greater in number than the second diode elements DS2.

Among the 12 diode elements DS, the five diode elements DS on the side opposite to the drain terminal 15 are the third diode elements DS3. That is, the five diode elements DS corresponding to the “No. 8” to “No. 12” diodes among the diodes “No. 1” to “No. 12” are the third diode elements DS3.

The cathode potentials applied to the five diode elements DS are in the range of 5.4V to 27V, inclusive. The element withstand voltage of the third diode elements DS3 is approximately 30V. The element withstand voltage of the third diode elements DS3 exceeds the cathode potentials applied to the “No. 8” to “No. 12” diode elements DS. That is, the element withstand voltage of the third diode elements DS3 satisfies the element withstand voltage required of the “No. 8” and “No. 12” diode elements DS.

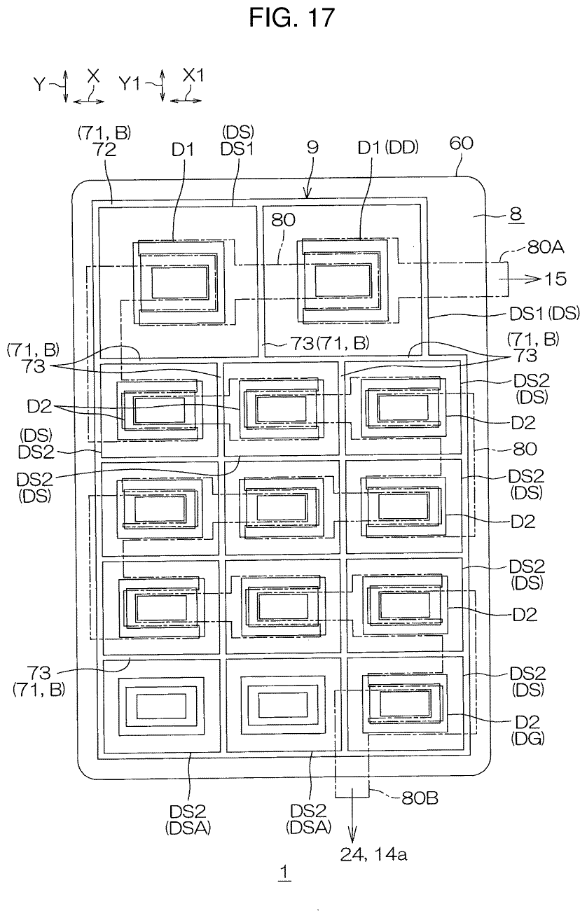

The embodiment of FIGS. 1 and 16C shows Embodiment 1 of an arrangement layout of the first diode elements DS1 and the second diode elements DS2. With reference to FIGS. 17 to 23, a variation of an arrangement layout example of the first diode elements DS1 and the second diode elements DS2 will be described below.

In Embodiments 2 to 6, the plurality of diode elements DS are arrayed in a matrix along the first direction X and the second direction Y in the diode formation region 8. The two diode elements DS adjacent to each other in the first direction X and the second direction Y are all in contact with each other. That is, the two adjacent diode elements DS share a common element boundary B with each other.

FIG. 17 is a view showing Embodiment 2 of an arrangement layout of the first diode element DS1 and the second diode element DS2.

In Embodiment 2, specifically 14 diode elements DS are arrayed in five rows and three columns. Among the five rows extending in the first direction X, the row at the farthest end in the second direction Y (top side in FIG. 17) has two first diode elements DS1 arrayed in the first direction X. The remaining four rows have three first diode elements DS1 arrayed in the first direction X.

For ease of explanation, the five rows extending in the first direction X are referred to as the first row, second row, third row, fourth row, and fifth row (same applies to the description of Embodiments 2 to 6 below).

The first diode elements DS1 are only included in the first row and not in the second to fifth rows. The second diode elements DS2 are only included in the second to fifth rows and not in the first row. That is, the two first diode elements DS1 and the 12 second diode elements DS2 are arrayed so as to be included in different rows.

One element boundary B between the two first diode elements DS1 in the first row is offset in the first direction X from the two element boundaries B between the three second diode elements DS2 in the second row and beyond. That is, one first diode element DS1 in the first row opposes, in the second direction Y, two second diode elements DS2 each in the second row and beyond.

The two second diode elements DS2 among the 12 second diode elements DS2 are not electrically connected to the first diode elements DS1 or the other second diode elements DS2. That is, these two second diode elements DS2 are not included in the diode group 9. The second diode elements DS2 are diode elements DSA included in another circuit.

That is, in Embodiment 2, the plurality of diode elements DS connected in series to each other include two first diode elements DS1 and 10 diode elements DS2.

As shown in FIG. 17, the plurality of diode elements DS are connected in series to each other by the plurality of connective wiring lines 80. In a plan view, the plurality of connective wiring lines 80 connect three second diode elements DS2 included in each row in a meander from the first row to the fifth row in the stated order.

The first diode element DS1 closest to the drain terminal 15 (first diode element DS1 corresponding to drain-side diode DD) is disposed towards one side in the first direction X (right side in FIG. 17) in the first row. The drain-side connective wiring line 80A is connected to the first diode element DS1 (drain-side diode DD).

The second diode element DS2 furthest to the side opposite the drain terminal 15 (ground-side diode DG) is disposed towards one end in the first direction X (right side in FIG. 17) in the fifth row. One end of an opposite-side connective wiring line 80B is connected to the second diode element DS2. The other end of the opposite-side connective wiring line 80B is electrically connected to the gate control circuit 24 (FIG. 5A) or the ground terminal 14a (FIG. 5B).

The other two diode elements DSA are disposed at the remaining positions in the fifth row.

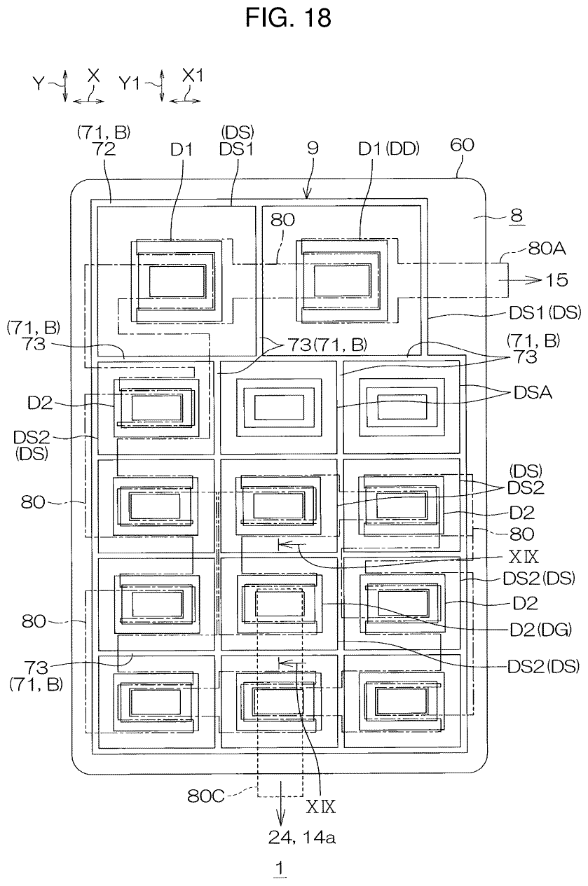

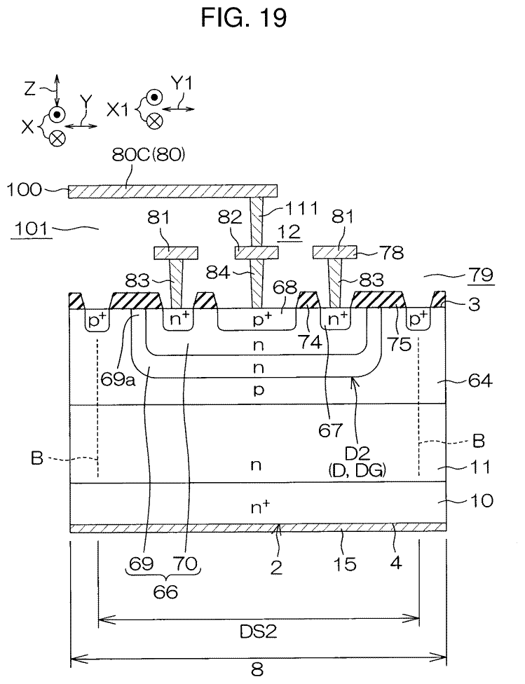

FIG. 18 is a view showing Embodiment 3 of an arrangement layout of the first diode element DS1 and the second diode element DS2. FIG. 19 is an enlarged cross-sectional view along the line XIX-XIX in FIG. 18.

The arrangement layout of the first diode element DS1 and the second diode element DS2 in Embodiment 3 is the same as the arrangement layout according to Embodiment 2 (FIG. 17).

The plurality of diode elements DS are connected in series to each other by the plurality of connective wiring lines 80. The plurality of connective wiring lines 80 extend along the peripheral edge of the diode formation region 8 so as to surround the second diode element DS2 (ground-side diode DG) furthest to the opposite side of the drain terminal 15.

The second diode element DS2 furthest to the side opposite to the drain terminal 15 (ground-side diode DG) is disposed towards the center in the first direction X in the fourth row, for example. An opposite-side connective wiring line 80C included in the second wiring layer 100 (see FIG. 19) is connected to the second diode element DS2. The other end of the opposite-side connective wiring line 80C is connected to the gate control circuit 24 (FIG. 5A) or the ground terminal 14a (FIG. 5B).

The plurality of connective wiring lines 80 connect the plurality of second diode elements DS2 in a spiral, with the end point being the second diode element DS2 including the ground-side diode DG. In other words, the plurality of second diode elements DS2 are arrayed in a spiral.

The other two diode elements DSA are disposed at the second row.

With reference to FIG. 19, in this embodiment, the interlayer insulating layer 12 includes a second insulating layer 101 formed on the first insulating layer 79. Also, the semiconductor device 1 includes a second wiring layer 100 disposed in the interlayer insulating layer 12. The second wiring layer 100 is formed on the second insulating layer 101. The opposite-side connective wiring line 80C is included in the second wiring layer 100.

The semiconductor device 1 includes a fifth plug electrode 111. The fifth plug electrode 111 transmits the anode potential to the anode region 68 of the ground-side diode DG. The opposite-side connective wiring line 80C is connected to the top end of the fifth plug electrode 111. The second plug electrode 84 is connected to the bottom end of the fifth plug electrode 111 via the anode wiring line 82. The opposite-side connective wiring line 80C is electrically connected to the anode region 68 of the ground-side diode DG via the fifth plug electrode 111 and the second plug electrode 84.

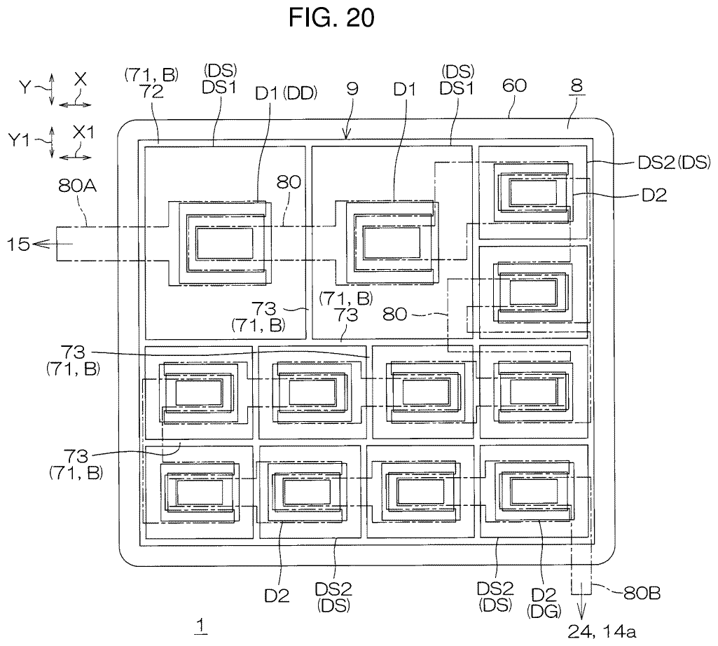

FIG. 20 is a view showing Embodiment 4 of an arrangement layout of the first diode element DS1 and the second diode element DS2.

In Embodiment 4, 12 diode elements DS are arrayed in four rows and four columns. The plurality of diode elements DS connected in series to each other include two first diode elements DS1 and 10 diode elements DS2.

Among the four rows extending in the first direction X, the first row has two first diode elements DS1 arrayed in the first direction X.

The two first diode elements DS1 are formed so as to straddle the first row and the second row. The 10 second diode elements DS2 are disposed one each in the first row and the second row and four each in the third row and fourth row.

One element boundary B between the two first diode elements DS1 is offset in the first direction X from the two element boundaries B between the three second diode elements DS2 in the third row and beyond. That is, one first diode element DS1 opposes, in the second direction Y, two second diode elements DS2 each in the third row and beyond.

Also, one first diode element DS1 opposes, in the first direction X, two second diode elements DS2 each in the first row and the second row. In other words, the first diode element DS1 is surrounded in two directions by the plurality of second diode elements DS2.

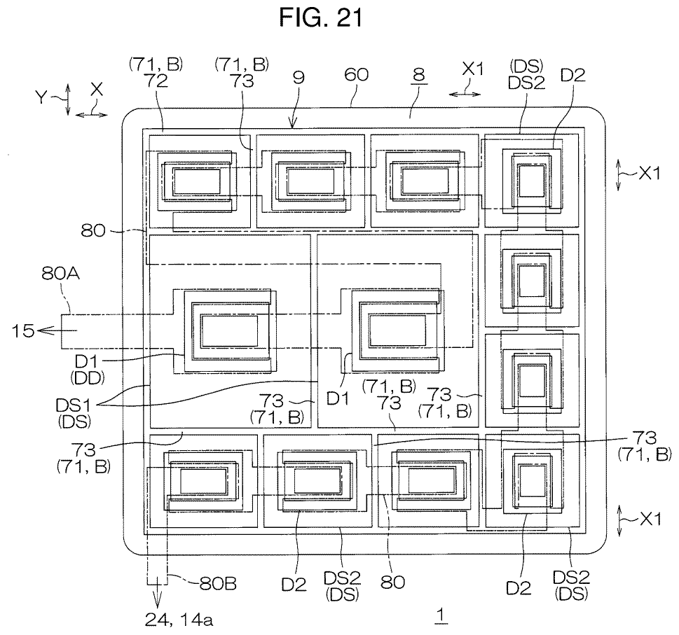

FIG. 21 is a view showing Embodiment 5 of an arrangement layout of the first diode element DS1 and the second diode element DS2.

In Embodiment 5, 12 diode elements DS are arrayed in four rows and four columns. The plurality of diode elements DS connected in series to each other include two first diode elements DS1 and 10 diode elements DS2.

Among the four rows extending in the first direction X, the second row has two first diode elements DS1 arrayed in the first direction X.

The two first diode elements DS1 are formed so as to straddle the second row and the third row. The 10 second diode elements DS2 are disposed one each in the second row and the third row and four each in the first row and the fourth row.

One element boundary B between the two first diode elements DS1 is offset in the first direction X from the two element boundaries B between the three second diode elements DS2 in the first row. That is, one first diode element DS1 opposes, in the second direction Y, two second diode elements DS2 in the first row.

One element boundary B between the two first diode elements DS1 is offset in the first direction X from the two element boundaries B between the three second diode elements DS2 in the fourth row. That is, one first diode element DS1 opposes, in the second direction Y, two second diode elements DS2 in the fourth row. In other words, the first diode element DS1 is surrounded in three directions by the plurality of second diode elements DS2.

Also, the four second diode elements DS2 included in the row at a furthest end in the first direction X (right side in FIG. 21), among the four rows extending in the second direction Y, differ by 90° in orientation (orientation of first element direction X1) from the other six second diode elements DS2.

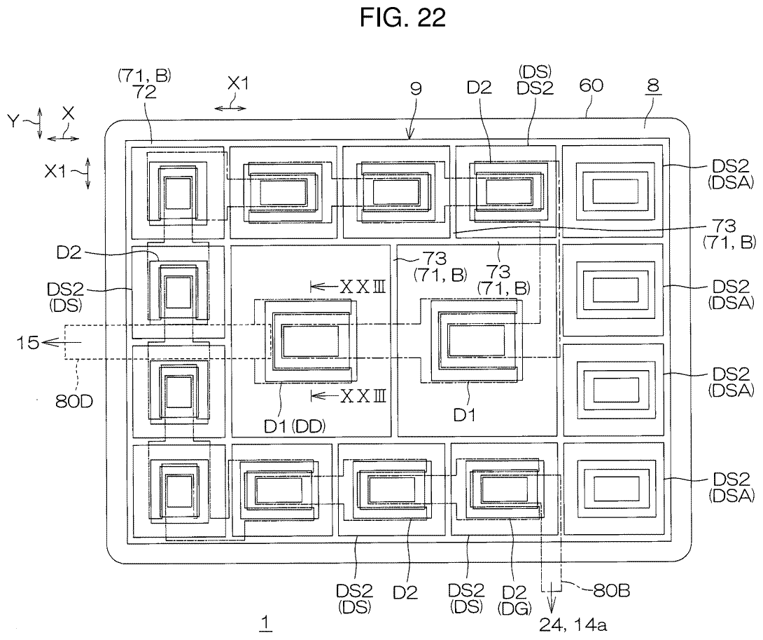

FIG. 22 is a view showing Embodiment 6 of an arrangement layout of the first diode element DS1 and the second diode element DS2.

In Embodiment 6, 16 diode elements DS are arrayed in four rows and five columns. The plurality of diode elements DS connected in series to each other include two first diode elements DS1 and 14 diode elements DS2.

Among the four rows extending in the first direction X, the second row has two first diode elements DS1 arrayed in the first direction X.

The two first diode elements DS1 are formed so as to straddle the second row and the third row. The 14 second diode elements DS2 are disposed two each in the second row and the third row and five each in the first row and the fourth row.

One element boundary B between the two first diode elements DS1 is offset in the first direction X from the two element boundaries B between the three second diode elements DS2 in the first row. That is, one first diode element DS1 opposes, in the second direction Y, two second diode elements DS2 in the first row.

One element boundary B between the two first diode elements DS1 is offset in the first direction X from the two element boundaries B between the three second diode elements DS2 in the fourth row. That is, one first diode element DS1 opposes, in the second direction Y, two second diode elements DS2 in the fourth row.

Also, one first diode element DS1 opposes, in the first direction X, two second diode elements DS2 (second diode elements DS2 in the second row and the third row).

The 14 second diode elements DS2 surround the periphery (entire periphery) of the two diodes. In other words, the first diode element DS1 is surrounded in four directions by the plurality of second diode elements DS2.

Also, the four second diode elements DS2 included in the row at a furthest end in the first direction X (left side in FIG. 22), among the four rows extending in the second direction Y, differ by 90° in orientation (orientation of first element direction X1) from the other 10 second diode elements DS2.

Also, the four second diode elements DS2 included in the row at a furthest end in the first direction X (right side in FIG. 22), among the four rows extending in the second direction Y, are the other diode elements DSA.

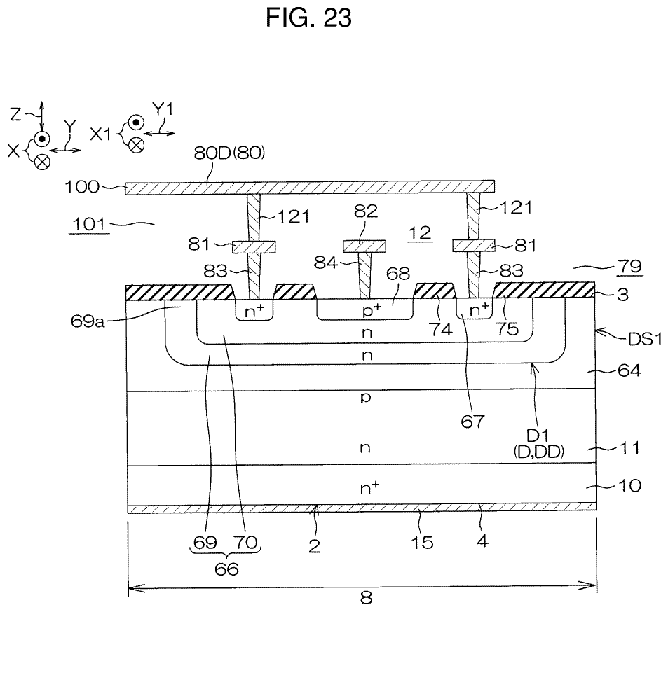

In this embodiment, the first diode element DS1 closest to the drain terminal 15 (first diode element DS1 corresponding to drain-side diode DD) and the first diode element DS1 including the drain-side diode DD are disposed towards the center in the first direction X in the second row and the third row. A drain-side connective wiring line 80D included in the second wiring layer 100 (see FIG. 23) is connected to the first diode element DS1. Aside from being in the second wiring layer 100, the drain-side connective wiring line 80D is an equivalent wiring line to the drain-side connective wiring line 80A, and includes the cathode wiring line 81 (FIG. 12) and the plurality of terminal plug electrodes 90 (FIG. 12).

With reference to FIG. 23, the semiconductor device 1 includes a sixth plug electrode 121. The sixth plug electrode 121 transmits the cathode potential to the cathode region 67 of the drain-side diode DD. The drain-side connective wiring line 80D is connected to the top end of the sixth plug electrode 121. The first plug electrode 83 is connected to the bottom end of the sixth plug electrode 121 via the cathode wiring line 81. The drain-side connective wiring line 80D is electrically connected to the cathode region 67 of the drain-side diode DD via the fifth plug electrode 111 and the first plug electrode 83.

In Embodiments 2 to 6, effects equivalent to those exhibited by the embodiment shown in FIGS. 1 to 16B and the like are exhibited.

The embodiments of the present disclosure were described above, but this disclosure can have even more aspects.

An example using two types of diode elements DS (second diode element DS2 and third diode element DS3) differing in outer peripheral distance as the diode elements DS having a shorter outer peripheral distance than the first diode element DS1 was presented, but three or more types of diode elements DS each having different outer peripheral distances from each other may be used.

In the embodiments above, an example was described in which the first conductivity type is the p type and the second conductivity type is the n type, but alternatively, a configuration may be adopted in which the first conductivity type is the n type and the second conductivity type is the p type. The specific configuration in this case can be attained by replacing the n-type regions with the p-type regions and replacing the p-type regions with the n-type regions in the above descriptions and attached drawings.

In the embodiments of the present disclosure, all aspects are examples and should not be interpreted as being limiting, and it is intended that all aspects can be modified.

From the specification and the drawings, the characteristics enumerated below can be extracted. Below, numerals in the parentheses indicate the corresponding constituent elements in the embodiments above, but the clauses should not be interpreted as being limited to the embodiments.

### [Note 1-1]

A semiconductor device (1), including:
a chip (2) having a first main surface (3) and a second main surface (4) opposite to the first main surface (3);
a first conductivity-type first impurity region (64) formed in a surface layer of the first main surface (3); and
a plurality of diode element (DS) that are included in clamp circuits (30, 35) connected to a power source terminal (15) and that are directly connected to each other, the plurality of diode elements (DS) being formed in a surface layer of the first well region (64) in a diode formation region (8) set in the first main surface (3),
wherein the diode elements (DS) each include second conductivity-type second impurity regions (66) that are formed at a gap from each other in a direction along the first main surface (3) in a surface layer of the first impurity region (64) in the diode formation region (8), and a plurality of anode regions (68) and a plurality of cathode regions (67) that are formed in a surface layer of the second impurity regions (66),
wherein the plurality of diode elements (DS) include at least one first diode element (DS1), and at least one second diode element (DS2) with a shorter outer peripheral distance than the first diode element (DS1), and
wherein the first diode element (DS1) is connected to the power source terminal (15) side of the second diode element.

### [Note 1-2]

The semiconductor device (1) according to Note 1-1,
wherein the first diode element (DS1) and the second diode element (DS2) have a same reverse direction voltage as each other.

### [Note 1-3]

The semiconductor device (1) according to Note 1-1 or Note 1-2,
wherein the second diode element (DS2) has a lower element withstand voltage than that of the first diode element (DS1).

### [Note 1-4]

The semiconductor device (1) according to any one of Notes 1-1 to 1-3,
wherein the first impurity region (64) is configured to have applied thereto a ground potential.

### [Note 1-5]

The semiconductor device (1) according to any one of Notes 1-1 to 1-4,
wherein a plurality of the second diode elements (DS2) are provided.

### [Note 1-6]

The semiconductor device (1) according to Note 1-5,
wherein the first diode element (DS1) is connected to the power source terminal (15) side of all of the second diode elements (DS2).

### [Note 1-7]

The semiconductor device (1) according to any one of Notes 1-1 to 1-6,
wherein the second impurity region (66) includes a first concentration region (69) formed in the surface layer of the first main surface (3), and a second concentration region (70) that is formed in a surface layer of the first concentration region (69) and has a higher second conductivity-type impurity concentration than the first impurity region (64), and
wherein the anode region (68) and the cathode region (67) are formed in a surface layer of the second concentration region (70).

### [Note 1-8]

The semiconductor device (1) according to Note 1-7,
wherein, in the first concentration region (69) of the second diode element (DS2), a surrounding section (69a) that surrounds an outer periphery of the second concentration region (70) of the second diode element (DS2) has a second width (W21) in a first element direction (X1) that is narrower than a first width (W1) in the first element direction (X1) of a surrounding section (69a) that surrounds an outer periphery of the second concentration region (70) of the first diode element (DS1) in the first concentration region (69) of the first diode element (DS1).

### [Note 1-9]

The semiconductor device (1) according to Note 1-7 or Note 1-8,
wherein a second distance (L21) that is a distance in the first element direction (X1) of the outer periphery of the second concentration region (70) of the second diode element (DS2) is shorter than a first distance (L1) that is a distance in the first element direction (X1) of the outer periphery of the first concentration region (69) of the first diode element (DS1).

### [Note 1-10]

The semiconductor device (1) according to any one of Notes 1-7 to 1-9,
wherein a fourth distance (L23) that is a distance in the first element direction (X1) of the outer periphery of the second concentration region (70) of the second diode element (DS2) is shorter than a third distance (L3) that is a distance in the first element direction (X1) of the outer periphery of the second concentration region (70) of the first diode element (DS1).

### [Note 1-11]

The semiconductor device (1) according to any one of Notes 1-1 to 1-10,
wherein the anode region (68) and the cathode region (67) are formed at a gap from each other in a direction along the first main surface (3), and
wherein a first gap (W5) in the first element direction between the anode region (68) and the cathode region (69) in the first diode element (DS1) is equal to a second gap (W65) in the first element direction between the anode region (68) and the cathode region (67) in the second diode element (DS2).

### [Note 1-12]

The semiconductor device (1) according to Note 1-11,
wherein a third width (W3) in the first element direction (X1) of the anode region (68) in the first diode element (DS1) is equal to a fourth width (W63) in the first element direction (X1) of the anode region (68) in the second diode element (DS2), and
wherein a fifth width (W4) in the first element direction (X1) of the cathode region (67) in the first diode element (DS1) is equal to a sixth width (W64) in the first element direction (X1) of the cathode region (67) in the second diode element (DS2).

### [Note 1-13]

The semiconductor device (1) according to Note 1-9 or Note 1-10,
wherein the plurality of diode elements (DS) each further include a plurality of second conductivity-type guard ring regions (71) formed so as to surround the periphery of a plurality of the second impurity regions (66), a plurality of the anode regions (68), and a plurality of the cathode regions (67), and
wherein a fourth gap between the outer periphery of the second impurity region (66) of the second diode element (DS2) and the guard ring region (71) is narrower than a third gap (W2) between the outer periphery of the second impurity region (66) of the first diode element (DS1) and the guard ring region (71).

### [Note 1-14]

The semiconductor device (1) according to any one of Notes 1-1 to 1-7,
wherein the plurality of diode elements (DS) each further include a plurality of second conductivity-type guard ring regions (71) formed so as to surround the periphery of a plurality of the second impurity regions (66), a plurality of the anode regions (68), and a plurality of the cathode regions (67), and
wherein a fourth gap (W22) between the outer periphery of the second impurity region (66) of the second diode element (DS2) and the guard ring region (71) is narrower than a third gap (W2) between the outer periphery of the second impurity region (66) of the first diode element (DS1) and the guard ring region (71).

### [Note 1-15]

The semiconductor device (1) according to any one of Notes 1-1 to 1-14,
wherein a plurality of the first diode elements (DS1) and the second diode elements (DS2) are provided, and
wherein a sixth gap (W26) between the second impurity regions (46) of two of the opposing second diode elements (DS2) is narrower than a fifth gap (W6) between the second impurity regions (46) of two of the opposing first diode elements (DS1).

### [Note 1-16]

The semiconductor device (1) according to any one of Notes 1-4 to 1-6,
wherein the plurality of diode elements (DS) are arranged in a matrix along a first direction (X) and a second direction (Y) that intersects with the first direction (X), the matrix including the first diode element (DS1) and a plurality of the second diode elements (DS2) in differing rows.

### [Note 1-17]

The semiconductor device (1) according to Note 1-5 or Note 1-6,
wherein the plurality of diode elements (DS) are arranged in a matrix along a first direction (X) and a second direction (Y) that intersects with the first direction (X), and wherein the plurality of second diode elements (DS2) oppose one of the diode elements (DS) in the second direction (Y).

### [Note 1-18]

The semiconductor device (1) according to any one of Notes 1-5, 1-6, and 1-17,
wherein a plurality of the second diode elements (DS2) are arrayed in a spiral.

### [Note 1-19]

The semiconductor device (1) according to any one of Notes 1-5, 1-6, 1-17, and 1-18,
wherein a plurality of the second diode elements (DS2) are arranged so as to surround a periphery of the first diode element (DS1).

### [Note 1-20]

The semiconductor device (1) according to any one of Notes 1-5, 1-6, and 1-17 to 1-19,
wherein a plurality of the second diode elements (DS2) include a first element (DS2) with a shorter outer peripheral distance in a first element direction (X1) than the first diode element (DS1) and a second element (DS3) with a shorter outer peripheral distance in a first element direction (X1) than the first element (DS2), and
wherein the first element (DS2) is connected to the power source terminal (15) side of the second element (DS3).

### [Note 1-21]

The semiconductor device (1) according to any one of Notes 1-1 to 1-20,
wherein the power source terminal (15) covers the second main surface (4),
wherein the chip (2) further includes a first semiconductor region (11) formed in the surface layer of the first main surface (3) so as to be electrically connected to the power source terminal (15), and
a connective wiring line (80A) that connects cathodes of the plurality of diode elements (D) to the first semiconductor region (11), and
wherein the first impurity region (64) is formed in the surface layer of the first semiconductor region (11).

### [Note 1-22]

The semiconductor device (1) according to Note 1-5 or Note 1-6,
wherein the first diode elements (DS1) are fewer in number than the second diode elements (DS2).

What is claimed is:

1. A semiconductor device, comprising:
a chip having a first main surface and a second main surface opposite to the first main surface; and
a plurality of diode elements that are connected in series to each other, and that are included in a clamp circuit connected to a power source terminal,
wherein the plurality of diode elements each include a first conductivity-type first impurity region formed in a surface layer of the first main surface in a diode formation region set in the first main surface, a plurality of second conductivity-type second impurity regions that are formed at a gap from each other in a direction along the first main surface in a surface layer of the first impurity region, and a plurality of anode regions and a plurality of cathode regions that are formed in a surface layer of the second impurity regions,
wherein the plurality of diode elements include a first diode element, and a second diode element with a shorter outer peripheral distance than an outer peripheral distance of the first diode element, and
wherein the first diode element is connected to a power source terminal side of the second diode element.

2. The semiconductor device according to claim 1,
wherein the first diode element and the second diode element have a same reverse direction voltage as each other.

3. The semiconductor device according to claim 1,
wherein the second diode element has a lower element withstand voltage than an element withstand voltage of the first diode element.

4. The semiconductor device according to claim 1,
wherein the first impurity region is configured to have applied thereto a ground potential.

5. The semiconductor device according to claim 1,
wherein a plurality of the second diode elements are provided.

6. The semiconductor device according to claim 5,
wherein the first diode element is connected to a power source terminal side of all of the second diode elements.

7. The semiconductor device according to claim 1,
wherein a second impurity region includes a first concentration region formed in the surface layer of the first main surface, and a second concentration region that is formed in a surface layer of the first concentration region and has a higher second conductivity-type impurity concentration than the first impurity region, and
wherein the anode region and the cathode region are formed in a surface layer of the second concentration region.

8. The semiconductor device according to claim 7,
wherein, in the first concentration region of the second diode element, a surrounding section that surrounds an outer periphery of the second concentration region of the second diode element has a second width in a first element direction that is narrower than a first width in the first element direction of a surrounding section that surrounds an outer periphery of the second concentration region of the first diode element in the first concentration region of the first diode element.

9. The semiconductor device according to claim 8,
wherein a second distance that is a distance in the first element direction between ends of the outer periphery of the second concentration region of the second diode element is shorter than a first distance that is a distance in the first element direction between ends of the outer periphery of the first concentration region of the first diode element.

10. The semiconductor device according to claim 8,
wherein a fourth distance that is a distance in the first element direction between ends of the outer periphery of the second concentration region of the second diode element is shorter than a third distance that is a distance in the first element direction between ends of the outer periphery of the second concentration region of the first diode element.

11. The semiconductor device according to claim 9,
wherein the anode region and the cathode region are formed at a gap from each other in a direction along the first main surface, and
a first gap in the first element direction between the anode region and the cathode region in the first diode element is equal to a second gap in the first element direction between the anode region and the cathode region in the second diode element.

12. The semiconductor device according to claim 11,
wherein a third width in the first element direction of the anode region in the first diode element is equal to a fourth width in the first element direction of the anode region in the second diode element, and
wherein a fifth width in the first element direction of the cathode region in the first diode element is equal to a sixth width in the first element direction of the cathode region in the second diode element.

13. The semiconductor device according to claim 9,
wherein the plurality of diode elements each further include a plurality of second conductivity-type guard ring regions formed so as to surround a periphery of the plurality of the second impurity regions, the plurality of the anode regions, and the plurality of the cathode regions, and
wherein a fourth gap between an outer periphery of the second impurity region of the second diode element and a guard ring region is narrower than a third gap between an outer periphery of the second impurity region of the first diode element and the guard ring region.

14. The semiconductor device according to claim 1,
wherein the plurality of diode elements each further include a plurality of second conductivity-type guard ring regions formed so as to surround a periphery of the plurality of the second impurity regions, the plurality of the anode regions, and the plurality of the cathode regions, and
wherein a fourth gap between an outer periphery of a second impurity region of the second diode element and a guard ring region is narrower than a third gap between an outer periphery of a second impurity region of the first diode element and the guard ring region.

15. The semiconductor device according to claim 5,
wherein a plurality of the first diode elements and the second diode elements are provided, and
wherein a sixth gap between second impurity regions of two of opposing second diode elements is narrower than a fifth gap between second impurity regions of two of opposing first diode elements.

16. The semiconductor device according to claim 5,
wherein the plurality of diode elements are arranged in a matrix along a first direction and a second direction that intersects with the first direction, the matrix including the first diode element and a plurality of the second diode elements in differing rows.

17. The semiconductor device according to claim 5,
wherein the plurality of diode elements are arranged in a matrix along a first direction and a second direction that intersects with the first direction, and
wherein the plurality of second diode elements oppose one of the first diode elements in the second direction.

18. The semiconductor device according to claim 5,
wherein the plurality of the second diode elements are connected in a spiral.

19. The semiconductor device according to claim 5,
wherein the plurality of the second diode elements are arranged so as to surround a periphery of the first diode element.

20. The semiconductor device according to claim 5,
wherein the plurality of the second diode elements include a first element with a shorter outer peripheral distance in a first element direction than the outer peripheral distance of the first diode element and a second element with a shorter outer peripheral distance in a first element direction than the outer peripheral distance of the first element, and
wherein the first element is connected to a power source terminal side of the second element.
